(19) United States
(12) Patent Application Publication
(10) Pub. No.: US 2024/0363462 A1
(43) Pub. Date: Oct. 31, 2024

(54) EFFICIENT REDISTRIBUTION LAYER TOPOLOGY FOR HIGH-POWER SEMICONDUCTOR PACKAGES

(71) Applicant: TEXAS INSTRUMENTS INCORPORATED, Dallas, TX (US)

(72) Inventors: Vivek Swaminathan SRIDHARAN, Dallas, TX (US); Hung-Yun LIN, Murphy, TX (US); Qiao CHEN, Flower Mound, TX (US)

(21) Appl. No.: 18/309,642

(22) Filed: Apr. 28, 2023

(51) Int. Cl. H01L 23/31; H01L 21/56; H01L 23/00; H01L 23/538

(52) U.S. Cl. CPC H01L 23/3114; H01L 21/565; H01L 23/3128; H01L 23/5389; H01L 24/05; H01L 24/13; H01L 2224/0233; H01L 2224/0401; H01L 2224/04105; H01L 2224/05093; H01L 2224/13026; H01L 2924/15311

(57) ABSTRACT

In some examples, a package comprises a die having a device side with circuitry formed therein; a passivation layer abutting the device side; and first and second vias coupling to the device side and extending through the passivation layer. The package includes first and second metal layers coupled to the first and second vias, respectively, the first and second metal layers abutting the passivation layer. The package includes an insulation layer abutting the first and second metal layers and separating the first and second metal layers, the insulation layer having an orifice in vertical alignment with the second metal layer. The package includes a third metal layer coupled to the second metal layer through the orifice, the third metal layer vertically aligned with the first and second metal layers. The package comprises a conductive member coupled to the third metal layer. The package includes a mold compound covering package components.

### BACKGROUND

During manufacture, semiconductor chips (also commonly referred to as “dies”) are typically mounted on die pads of lead frames and are wire-bonded, clipped, or otherwise coupled to leads of the lead frame. Other devices may similarly be mounted on a lead frame pad. The assembly is later covered in a mold compound, such as epoxy, to protect the assembly from potentially damaging heat, physical trauma, moisture, and other deleterious factors. The finished assembly is called a semiconductor package or, more simply, a package. The leads are exposed to surfaces of the package and are used to electrically couple the packaged chip to devices outside of the chip.

However, other types of packages, commonly known as flip-chip packages, are configured differently than described above. Flip-chip packages include a die, metallic bumps (e.g., solder bumps), and a redistribution layer (RDL) that interfaces between the die and the metallic bumps so that signals are routed appropriately between the bumps and the active circuitry formed on the die. Examples of such flip-chip packages include chip scale packages (CSPs), such as wafer chip scale packages (WCSPs).

### SUMMARY

In some examples, a package comprises a die having a device side with circuitry formed therein; a passivation layer abutting the device side; and first and second vias coupling to the device side and extending through the passivation layer. The package includes first and second metal layers coupled to the first and second vias, respectively, the first and second metal layers abutting the passivation layer. The package includes an insulation layer abutting the first and second metal layers and separating the first and second metal layers, the insulation layer having an orifice in vertical alignment with the second metal layer. The package includes a third metal layer coupled to the second metal layer through the orifice, the third metal layer vertically aligned with the first and second metal layers. The package comprises a conductive member coupled to the third metal layer. The package includes a mold compound covering package components.

### BRIEF DESCRIPTION OF THE DRAWINGS

Some of the drawings described below depict part, but not all, of various structures in accordance with various examples. For example, some of the drawings depict parts of metal layers, but they do not depict the entirety of the metal layers. Such drawings are illustrated in this manner to enhance clarity and facilitate understanding for the reader.

FIG. 1 is a schematic diagram of an electronic device including a chip scale package (CSP) implementing an efficient redistribution layer (RDL) topology, in accordance with various examples.

FIG. 2 is a profile, cross-sectional view of a portion of an electronic device that includes a CSP implementing an efficient RDL topology, in accordance with various examples.

FIG. 3 is a profile, cross-sectional view of a portion of an electronic device that includes a CSP implementing another efficient RDL topology, in accordance with various examples.

FIGS. 4A-4I are schematic, layered, bottom-up views of differing efficient RDL topologies, in accordance with various examples.

FIGS. 5A-5G are a process flow of a technique for manufacturing a CSP implementing an efficient RDL topology, in accordance with various examples.

FIG. 5H is a flow diagram of a method for manufacturing a CSP implementing an efficient RDL topology, in accordance with various examples.

FIG. 6A is a profile, cross-sectional view of a semiconductor package implementing an efficient RDL topology and including a substrate adapted to provide data and power signals, in accordance with various examples.

FIG. 6B is a top-down view of a semiconductor package implementing an efficient RDL topology and including a substrate adapted to provide data and power signals, in accordance with various examples.

FIG. 6C is a perspective view of a semiconductor package implementing an efficient RDL topology and including a substrate adapted to provide data and power signals, in accordance with various examples.

FIG. 6D is a top-down, multi-layer view of a semiconductor package, in accordance with various examples.

FIG. 6E is a top-down, multi-layer view of a semiconductor package, in accordance with various examples.

FIG. 7A is a profile, cross-sectional view of a semiconductor package implementing an efficient RDL topology, in accordance with various examples.

FIG. 7B is a top-down view of a semiconductor package implementing an efficient RDL topology, in accordance with various examples.

FIG. 7C is a perspective view of a semiconductor package implementing an efficient RDL topology, in accordance with various examples.

FIG. 8A is a profile, cross-sectional view of a semiconductor package implementing an efficient RDL topology, in accordance with various examples.

FIG. 8B is a top-down view of a semiconductor package implementing an efficient RDL topology, in accordance with various examples.

FIG. 8C is a perspective view of a semiconductor package implementing an efficient RDL topology, in accordance with various examples.

FIG. 9A is a profile, cross-sectional view of a semiconductor package implementing an efficient RDL topology, in accordance with various examples.

FIG. 9B is a top-down view of a semiconductor package implementing an efficient RDL topology, in accordance with various examples.

FIG. 9C is a perspective view of a semiconductor package implementing an efficient RDL topology, in accordance with various examples.

FIG. 10A is a profile, cross-sectional view of a semiconductor package implementing an efficient RDL topology, in accordance with various examples.

FIG. 10B is a top-down view of a semiconductor package implementing an efficient RDL topology, in accordance with various examples.

FIG. 10C is a perspective view of a semiconductor package implementing an efficient RDL topology, in accordance with various examples.

FIG. 11A is a profile, cross-sectional view of a semiconductor package implementing an efficient RDL topology, in accordance with various examples.

FIG. 11B is a top-down view of a semiconductor package implementing an efficient RDL topology, in accordance with various examples.

FIG. 11C is a perspective view of a semiconductor package implementing an efficient RDL topology, in accordance with various examples.

### DETAILED DESCRIPTION

Various types of redistribution layers (RDLs) are used in chip scale packages (CSPs) to route electrical signals between the semiconductor dies of the CSPs to the solder balls of the CSPs. Many RDLs include passivation layers abutting the semiconductor die to protect the semiconductor die from external elements and stresses. These passivation layers have orifices that facilitate the transfer of electrical signals between the semiconductor die and metal layers of the RDL. In some RDLs, the passivation layers (called non-planar passivation layers) have non-uniform thicknesses, particularly adjacent to the orifices, where the passivation layers may include raised segments. These raised segments can be vulnerable to the deleterious effects of mechanical stress imparted by the solder ball and under bump metallization (UBM) coupled to the solder ball. To protect the passivation layer, and especially the raised segments, from such stresses, the passivation layer raised segments and orifices may be located relatively far away from the UBM. In this way, stresses from the UBM do not damage the passivation layer. However, such a topology is inefficient in its use of space.

Other RDLs eliminate the need to position the passivation layer raised segments and orifices far away from the UBM by eliminating the raised segments. Instead, such RDLs include passivation layers (called planar passivation layers) that have substantially uniform thicknesses without the raised segments, and such passivation layers also include multiple vias that facilitate electrical communication between the semiconductor die and the UBM. This topology enables the vias to be positioned anywhere, for example, directly below the UBM, which would not be possible with other types of passivation layers. However, RDLs with this topology still use space inefficiently because they include large capture pads, which are the metal layers positioned under the UBMs that couple the UBMs to the vias or to other metal layers, and further because they include large orifices between the capture pads and the UBMs, which limits flexibility in RDL topology design. Such large capture pads with large orifices cause a large amount of space to be used for each solder bump and UBM—space that could otherwise have been more efficiently used for other RDL features such as metal layers that connect to vias, other solder balls, etc. Such inefficient use of space results in undesirably large CSPs.

This disclosure describes various examples of an efficient RDL topology that solves the challenges described above. Specifically, the RDL includes a passivation layer abutting the semiconductor die of the CSP and a via extending through the passivation layer. The RDL includes a first metal layer abutting the via and an insulation layer abutting the first metal layer. The insulation layer has an orifice with a maximal horizontal dimension (diameter) of less than 50 microns. The RDL also includes a second metal layer abutting the insulation layer and adapted to couple to a solder ball. The second metal layer abuts the first metal layer at a point of contact defined by the orifice in the insulation layer. Because the orifice is relatively small, the size of the capture pad is reduced, and because the size of the capture pad is reduced, the space that would otherwise have been occupied by the capture pad may now instead be used for other RDL features, such as metal layers that connect to vias, other solder balls, etc. This topology has several advantages. For instance, the efficient use of space enables the package size to be reduced. The improved layout capability of this RDL improves the electromigration performance of the package at the lower metal levels of the semiconductor die. The topology also has application-specific benefits that result from the efficient use of space. For example, semiconductor dies implementing field effect transistors (FETs) and the RDL topology described herein may experience significant improvements in drain-source on resistance (R_{DS(ON))} and the elimination of FET metal layers while achieving comparable or superior performance. The efficient RDL topologies described herein may be implemented in a variety of semiconductor packages, including packages having specific RDL and other structural features that significantly enhance package performance. Examples of such efficient RDL topologies and packages containing such topologies are now described with reference to the drawings.

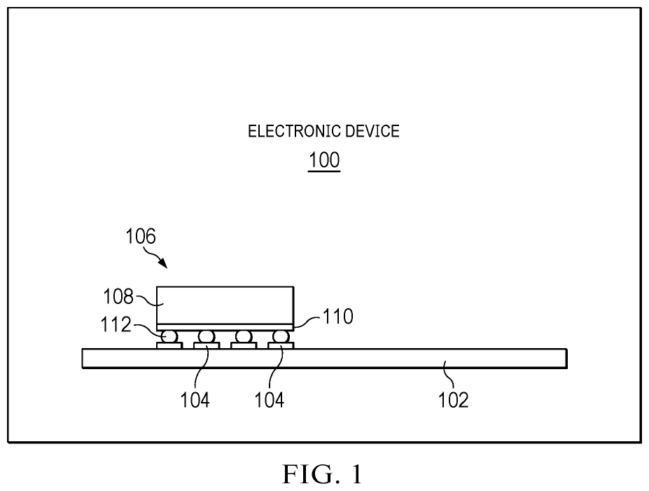

FIG. 1 is a schematic diagram of an electronic device including a chip scale package (CSP) implementing an efficient redistribution layer (RDL) topology, in accordance with various examples. Specifically, FIG. 1 shows an electronic device 100, such as in a laptop or notebook computer, a workstation, a smartphone, an automobile, an aircraft, a television, or any other suitable electronic device. The electronic device 100 includes a printed circuit board (PCB) 102, which may have coupled thereto any of a variety of electronic components, including processors, microcontrollers, memory, passive components, application-specific integrated circuits (ASICs), etc. The PCB 102 may include conductive terminals 104 (e.g., copper pads or traces) that facilitate coupling to such electronic components. The electronic device 100 includes a CSP 106 coupled to the conductive terminals 104. Although FIG. 1 shows one CSP, in examples, the electronic device 100 includes multiple CSPs. FIG. 1 shows the contents of the electronic device 100 in a profile, cross-sectional view.

The CSP 106 implements an efficient RDL topology in accordance with various examples. In examples, the CSP 106 includes a semiconductor die 108 that is coupled to an RDL 110 having an efficient topology. This description describes various such efficient RDL topologies, and in the genericized example RDL 110 of FIG. 1, the RDL 110 may implement any such RDL topology or variation thereof. The RDL 110 couples to solder balls (also called solder bumps) 112. The solder balls 112, in turn, couple to the conductive terminals 104. In this way, the circuitry formed in and/or on the semiconductor die 108 is configured to communicate with circuitry on the PCB 102 via the solder balls 112 and the RDL 110, which interfaces the circuitry of the semiconductor die 108 with the solder balls 112.

The size of the CSP 106 is determined at least in part by the topological efficiency of the RDL 110. Assuming the functionality of the CSP 106 remains static, an efficient use of space in the RDL 110 decreases the size of the RDL 110, thus decreasing the size of the CSP 106. Alternatively, assuming that the size of the CSP 106 remains static, an efficient use of space in the RDL 110 enables the incorporation of additional circuitry, and thus increased functionality, in the CSP 106.

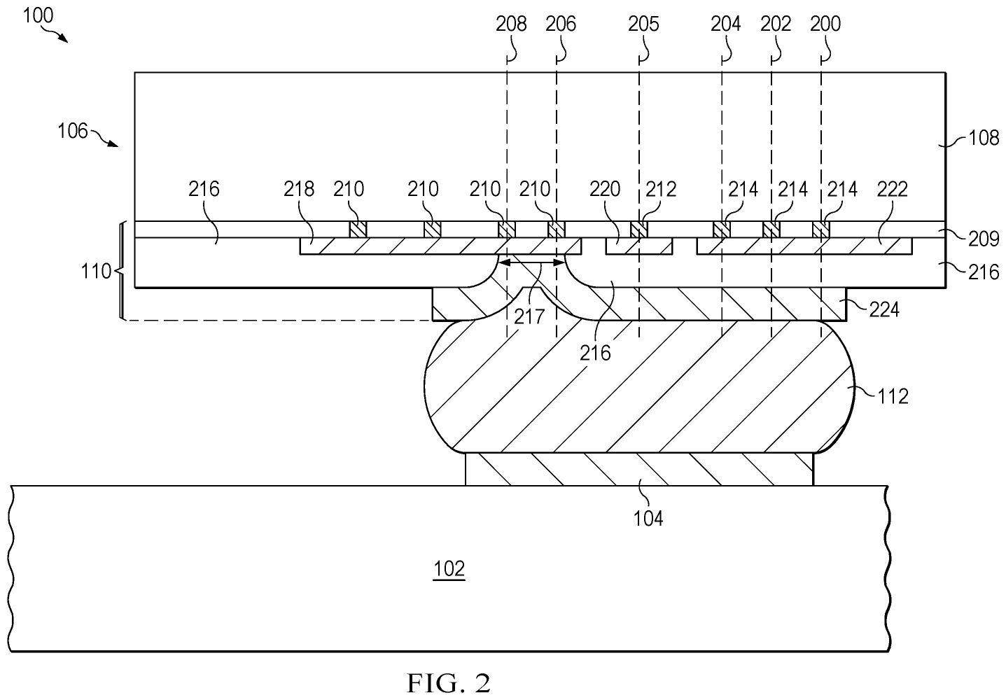

FIG. 2 is a profile, cross-sectional view of a portion of an electronic device that includes a CSP implementing an efficient RDL topology, in accordance with various examples. In particular, FIG. 2 shows a detailed view of the RDL 110. In examples, the RDL 110 includes a passivation layer 209 that is configured to protect the semiconductor die 108 from passivation. For example, the passivation layer 209 may be composed of a suitable oxide layer, a suitable nitride layer, or any other suitable type of layer (e.g., SiO₂, Si₃N₄, SiN, SiON). The passivation layer 209 may have any suitable thickness as may be appropriate for a given application. The passivation layer 209 may include multiple vias that extend through the passivation layer 209 and that facilitate the transfer of electrical signals through the passivation layer 209 (e.g., between a lower-level metal layer (e.g., copper or aluminum) in the semiconductor die 108 and the rest of the RDL 110). These vias, such as vias 210, 212, 214, may be composed of a suitable conductive material, such as a metal (e.g., tungsten, copper) or a metal alloy and may have any suitable shape and size (e.g., horizontal areas ranging from 0.0644 microns² to 6400 microns²). In examples, the passivation layer 209 is a planar passivation layer, meaning that the thickness of the passivation layer 209 is approximately uniform throughout. As used herein, a substantially uniform thickness is a thickness with no more than 1 micron of variation in thickness from the thickest to the thinnest segments. Stated in another way, in some examples, no part of the passivation layer 209 abuts a top surface (e.g., a surface abutting the semiconductor die 108) or a bottom surface (e.g., a surface abutting a metal layer 218, 220, 222) of any of the vias 210, 212, 214. Stated still another way, the top and bottom surfaces of the vias 210, 212, 214 are approximately flush with the top and bottom surfaces, respectively, of the passivation layer 209. As used herein, the term approximately flush means flush within a margin of plus or minus 1 micron. When the passivation layer 209 is planar, it is not vulnerable to mechanical stresses from the solder ball 112 after the solder ball 112 has been coupled to the PCB 102. No area of the passivation layer 209 is subject to significantly more stress than any other area of the passivation layer 209. Accordingly, because the passivation layer 209 is uniform in this sense, the vias 210, 212, 214 may be positioned as desired in the passivation layer 209. This is in contrast to other CSPs in which the passivation layer is non-planar and includes a raised segment near or on conductive terminals that electrically couple the metal layers of the RDL to the semiconductor die. In such CSPs, the non-planar areas of the passivation layer are vulnerable to the aforementioned mechanical stresses. Thus, the non-planar areas of the passivation layer, and thus the conductive terminals co-located with these non-planar areas of the passivation layer, are located relatively far away from the solder ball.

In examples, the RDL 110 further includes an insulation layer 216 (e.g., polyimide, polybenzoxazole benzocyclobutene) that abuts portions of the passivation layer 209, and also includes metal layers 218, 220, 222 that abut portions of the passivation layer 209. The RDL 110 also includes a metal layer 224 (also called an under bump metallization, or UBM), which may include at least one of copper, titanium, tungsten, and/or nickel and which may have an area ranging from 2000 microns² to 63200 microns². The insulation layer 216 and the metal layers 218, 220, 222, 224 are patterned to implement a topology that establishes desired connections between the solder ball 112 that couples to the metal layer 224 and the vias 210, 212, 214. In examples, the metal layers 218, 220, 222, 224 facilitate the transfer of electrical signals, and the insulation layer 216 insulates the metal layers 218, 220, 222 from each other, as shown. In examples, the metal layer 218 abuts the vias 210. In examples, the metal layer 220 abuts the via 212. In examples, the metal layer 222 abuts the vias 214. The metal layer 224 couples to the metal layer 218 via an orifice 217. The physical dimensions, including various lengths, widths, and thicknesses, of the insulation layer 216 and the metal layers 218, 220, 222 may vary as appropriate for a given application. In examples, each of the metal layers 218, 220, 222 is composed of copper or aluminum.

The metal layers 218, 224 couple to each other at the orifice 217. The orifice 217 thus defines the point of contact at which the metal layers 218, 224 couple to each other. In examples, the orifice 217 has a maximal horizontal size of less than 100 microns. In examples, the orifice 217 has a maximal horizontal size of less than 75 microns. In examples, the orifice 217 has a maximal horizontal size of less than 50 microns. In examples, the orifice 217 has a maximal horizontal size of less than 35 microns. In examples, the orifice 217 has a maximal horizontal size of less than 20 microns. In examples, the orifice 217 has a maximal horizontal size of less than 10 microns. A narrower orifice 217 generally enables a more efficient use of space in the RDL 110, because a narrower orifice 217 enables other metal layers, such as the metal layers 220 and 222, to be positioned closer to the metal layer 218. Another benefit of a narrower orifice 217 is that it enables flexibility of design by miniaturization of the metal layer 218. Miniaturization of the metal layer 218 enables flexible geometries to be designed for high electrical efficiency of circuitries such as field effect transistors. As a result, the RDL 110 topology is denser, and thus more efficient, than it would be if the orifice 217 were wider. In FIG. 2, vertical planes 200, 202, 204, 205, 206, 208 demonstrate the vertical alignment of various vias 210, 212, 214 with the metal layer 224, which is indicative of the increased density of the RDL 110 made possible by the relatively narrow orifice 217. The narrower the orifice 217, the more efficient the topology of the RDL 110. However, reducing the diameter of a conductor can reduce its current throughput. Accordingly, narrowing the orifice 217 can restrict current flow through the orifice 217. Current flow can also be restricted by electromigration effects at the interface of the metal layer 224 and the solder ball 112, and such effects may be more restrictive on current flow than the size of the orifice 217, meaning that these effects are the bottleneck on current flow, not the orifice 217. However, it is possible that the orifice 217 can be narrowed to such a degree that the orifice 217 becomes the primary restriction on current flow (e.g., the bottleneck). Thus, the specific maximal horizontal size of the orifice 217 may, in some examples, be chosen based on the current flow restrictions imposed by the aforementioned electromigration effects. Stated another way, restrictions on current flow caused by these effects and/or by the maximal horizontal size of the orifice 217 may be balanced with improvements in RDL 110 density and efficiency achieved with smaller maximal horizontal size of the orifice 217.

In examples, the maximal horizontal size of the orifice 217 is the maximal horizontal dimension in any direction in the horizontal plane. For example, if the orifice 217 has an obround shape, the maximal horizontal size may refer to the length of the obround in the horizontal plane. If the orifice 217 has a rectangular (or polygonal) shape, the maximal horizontal size may refer to the length of the rectangle in the horizontal plane. Similarly, if the orifice 217 has a circular shape, the maximal horizontal size may refer to the diameter or radius of the circle in the horizontal plane. In examples, the maximal horizontal size of the orifice 217 refers to the total horizontal area of the orifice 217 in the horizontal plane. Thus, for instance, if the orifice 217 is a circle, the total horizontal area may be determined as the product of pi and the radius of the circle squared. In some such examples, the maximal horizontal area of the orifice 217 is 32400 microns². In some such examples, the maximal horizontal area of the orifice 217 is 3000 microns². In some such examples, the maximal horizontal area of the orifice 217 is 1875 microns². In some such examples, the maximal horizontal area of the orifice 217 is 750 microns². In some such examples, the maximal horizontal area of the orifice 217 is 350 microns². In some such examples, the maximal horizontal area of the orifice 217 is 250 microns². In some such examples, the maximal horizontal area of the orifice 217 is 80 microns². In some such examples, the maximal horizontal area of the orifice 217 is 20 microns². In some such examples, the maximal horizontal area of the orifice 217 ranges from 20 microns² to 32400 microns². Other horizontal areas are contemplated and included in the scope of this disclosure.

The dimension(s) in which the maximal horizontal size is determined has implications on the RDL 110 topology and density. For example, if the orifice 217 is a rectangle with a length different than its width, then orienting the rectangle in different directions will result in differing possible RDL topologies. For instance, orienting the rectangle in a first direction may mean that certain metal layers may be positioned close to the orifice 217, while orienting the rectangle in a second direction may mean that those same metal layers cannot be positioned close to the orifice 217. Thus, not only the size of the orifice 217 but also its shape and orientation may impact the topology and density of the RDL 110 and thus are relevant factors to be considered when designing an RDL 110.

Other factors also may affect current throughput, such as the number and sizes of the vias 210, 212, 214 (which, in some examples, may have horizontal cross sectional dimensions ranging from 0.25 microns² up to 4000 microns²) as well as the number of metal layers that couple to the solder ball 112 and that couple to the semiconductor die 108. The maximal horizontal size, shape, and orientation of the orifice 217 are thus not mere design choices but rather have unexpected consequences for a variety of aspects of the CSP 106, including the topology and density of the RDL 110, current throughput between the solder ball 112 and the semiconductor die 108, number and sizes of the vias 210, 212, 214, connections between various metal layers, etc., each of which is a consideration in determining a suitable maximal horizontal size, shape, and orientation of the orifice 217.

In operation, electrical signals flow between the semiconductor die 108 and the PCB 102 via the conductive terminal 104, solder ball 112, metal layer 224, orifice 217, metal layer 218, and vias 210. The metal layers 220, 222 couple to other solder balls that are not expressly shown and that may be located away from the solder ball 112.

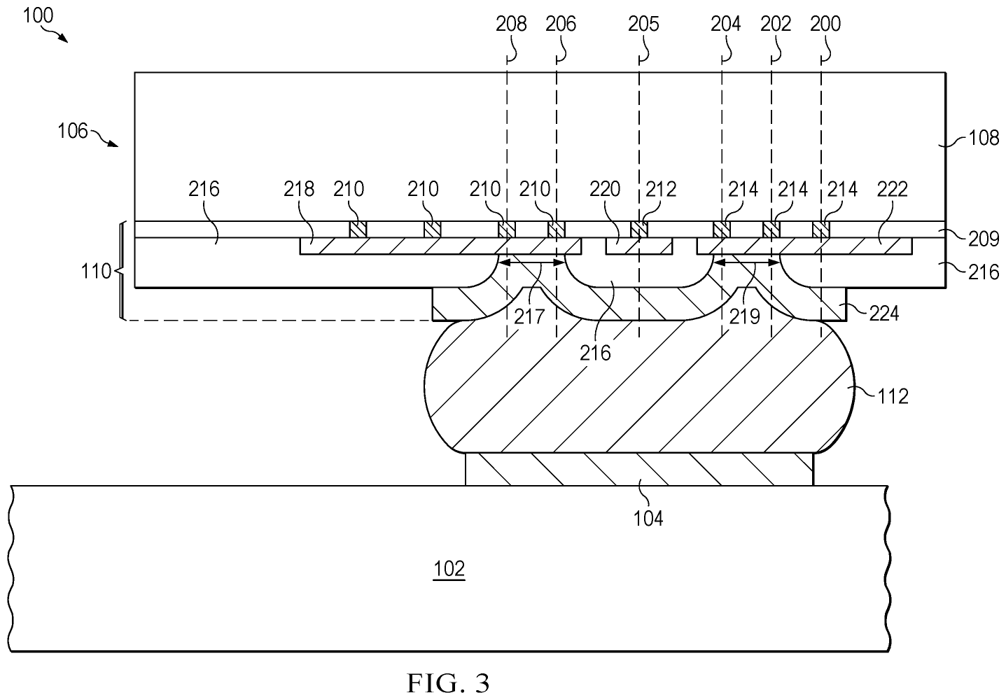

FIG. 3 is a profile, cross-sectional view of a portion of an electronic device that includes a CSP implementing another efficient RDL topology, in accordance with various examples. The CSP 106 of FIG. 3 is virtually identical to the CSP 106 of FIG. 2, except that the CSP 106 of FIG. 3 includes an orifice 219 through which the metal layer 224 couples to the metal layer 222. The orifice 219 is formed by the insulation layer 216, and the orifice 219 defines a point of contact at which the metal layers 222, 224 abut each other. Because the metal layer 224 couples to both the metal layers 218, 222, a communication pathway is established between the solder ball 112 and the vias 210, 214. The description provided above regarding the sizing of the orifice 217 also applies to the orifice 219. In examples, the orifices 217, 219 have the same shape but different sizes. In examples, the orifices 217, 219 have different shapes but the same size. In examples, the orifices 217, 219 have differing shapes and sizes. In examples, the orifices 217, 219 have the same shape and the same size.

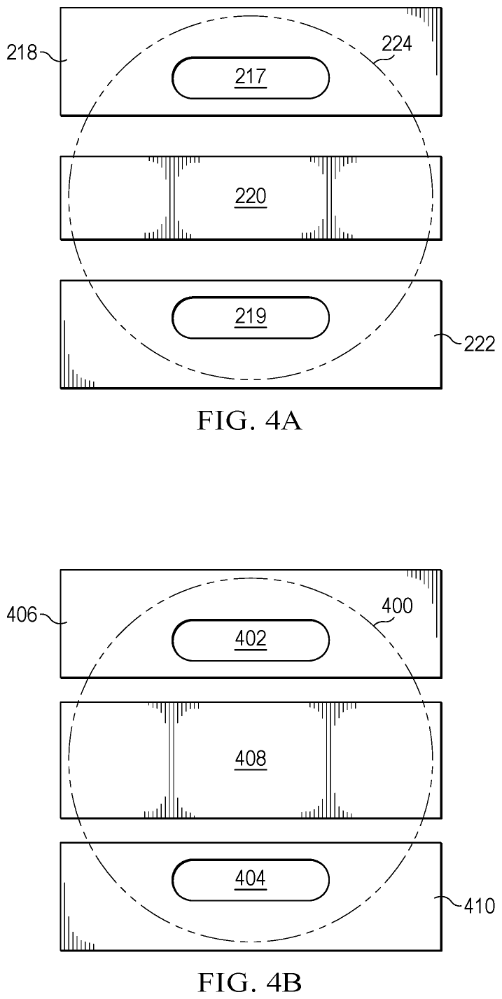

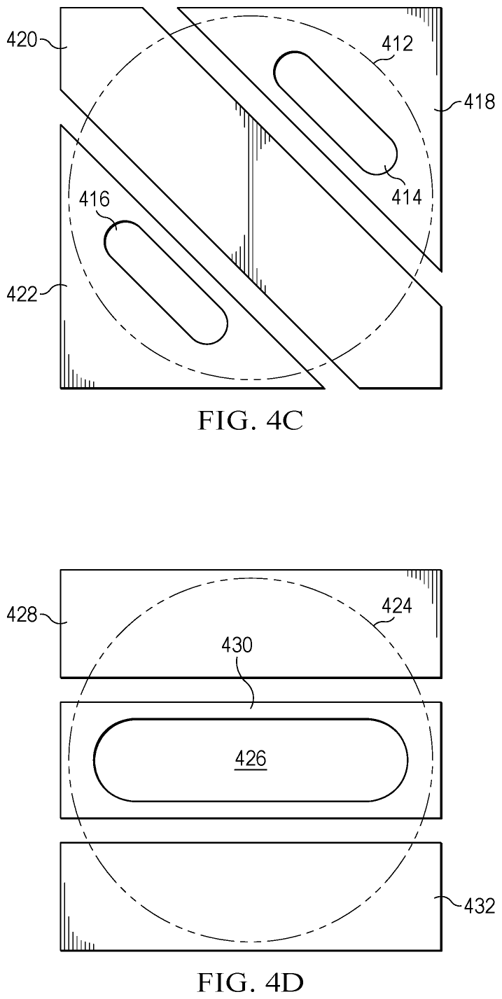

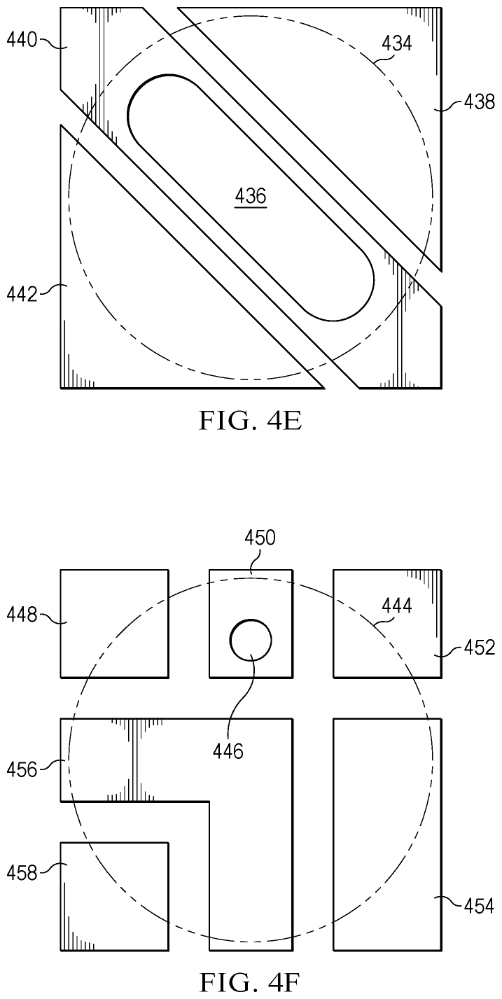

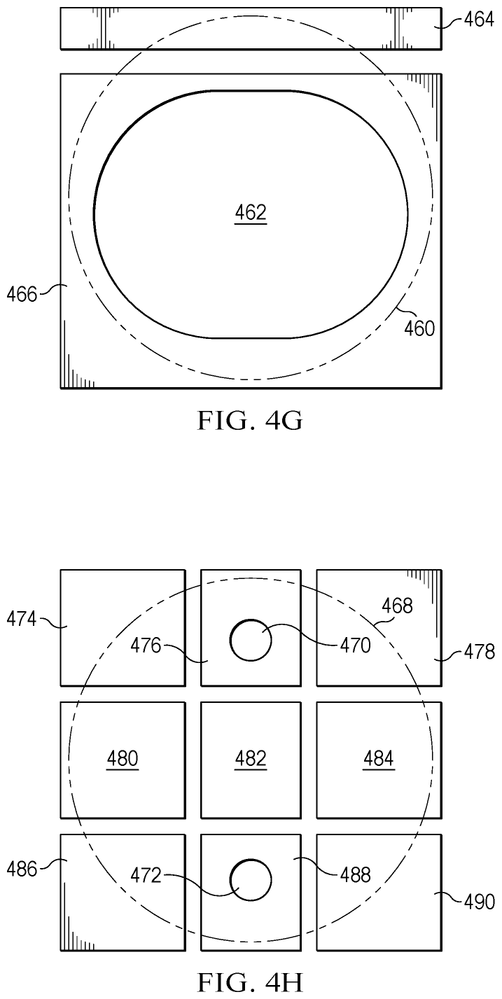

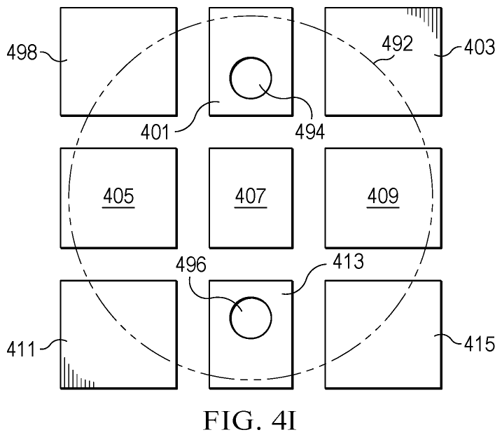

FIGS. 4A-4I are schematic, layered, bottom-up views of differing efficient RDL topologies, in accordance with various examples. In particular, FIG. 4A is a bottom-up view of the structure of FIG. 3, with the PCB 102, the conductive terminal 104, and the solder ball 112 excluded. As shown, the metal layer 224 couples to metal layers 218, 222 through the orifices 217, 219, respectively. FIG. 4A shows metal layer 222 present above the metal layer 224, but, as in FIG. 3, the metal layers 222, 224 do not couple to each other. FIG. 4A shows the orifices 217, 219 having horizontal, cross-sectional shapes that are obround. As described above, the orientations of the orifices 217, 219 can impact the topology of the RDL 110. For instance, if the orifices 217, 219 were kept the same size as shown in FIG. 4A but were rotated by 90 degrees, it may no longer be possible to accommodate the metal layer 220 in its current position, and thus some or all aspects (e.g., position, shape, orientation, size) of the metal layers 218, 220, and/or 222 would be adjusted accordingly.

FIG. 4B is a bottom-up view of another example CSP implementing the efficient RDL topology described herein. FIG. 4B shows a metal layer 400 coupled to the metal layers 406, 410 through the orifices 402, 404, respectively. The metal layers 400, 408 do not couple to each other. As in FIG. 4A, the horizontal, cross-sectional shapes of the orifices 402, 404 are obround.

FIG. 4C is a bottom-up view of another example CSP implementing the efficient RDL topology described herein. FIG. 4C shows a metal layer 412 coupled to the metal layers 418, 422 through the orifices 414, 416, respectively. The metal layers 412, 420 do not couple to each other. As FIG. 4C shows, the horizontal, cross-sectional shapes of the orifices 414, 416 are obround.

FIG. 4D is a bottom-up view of another example CSP implementing the efficient RDL topology described herein. FIG. 4D shows a metal layer 424 coupled to the metal layer 430 through the orifice 426. The metal layer 424 does not couple to the metal layers 428, 432. As FIG. 4D shows, the horizontal, cross-sectional shape of the orifice 426 is obround.

FIG. 4E is a bottom-up view of another example CSP implementing the efficient RDL topology described herein. FIG. 4E shows a metal layer 434 coupled to the metal layer 440 through an orifice 436. The metal layer 434 does not couple to metal layers 438, 442. As FIG. 4E shows, the horizontal, cross-sectional shape of the orifice 436 is obround.

FIG. 4F is a bottom-up view of another example CSP implementing the efficient RDL topology described herein. FIG. 4F shows a metal layer 444 coupled to metal layer 450 through an orifice 446. The metal layer 444 does not couple to metal layers 448, 452, 454, 456, or 458. As FIG. 4F shows, the horizontal, cross-sectional shape of the orifice 446 is circular.

FIG. 4G is a bottom-up view of another example CSP implementing the efficient RDL topology described herein. FIG. 4G shows a metal layer 460 coupled to metal layer 466 through an orifice 462. The metal layer 460 does not couple to metal layer 464. As FIG. 4G shows, the horizontal, cross-sectional shape of the orifice 462 is oval.

FIG. 4H is a bottom-up view of another example CSP implementing the efficient RDL topology described herein. FIG. 4H shows a metal layer 468 coupled to metal layers 476, 488 through orifices 470, 472, respectively. The metal layer 468 does not couple to metal layers 474, 478, 480, 482, 484, 486, or 490. As FIG. 4H shows, the horizontal, cross-sectional shapes of the orifices 470, 472 are circular.

FIG. 4I is a bottom-up view of another example CSP implementing the efficient RDL topology described herein. FIG. 4I shows a metal layer 492 coupled to metal layers 401, 413 through orifices 494, 496, respectively. The metal layer 492 does not couple to metal layers 498, 403, 405, 407, 409, 411, or 415. As FIG. 4I shows, the horizontal, cross-sectional shapes of the orifices 494, 496 are circular.

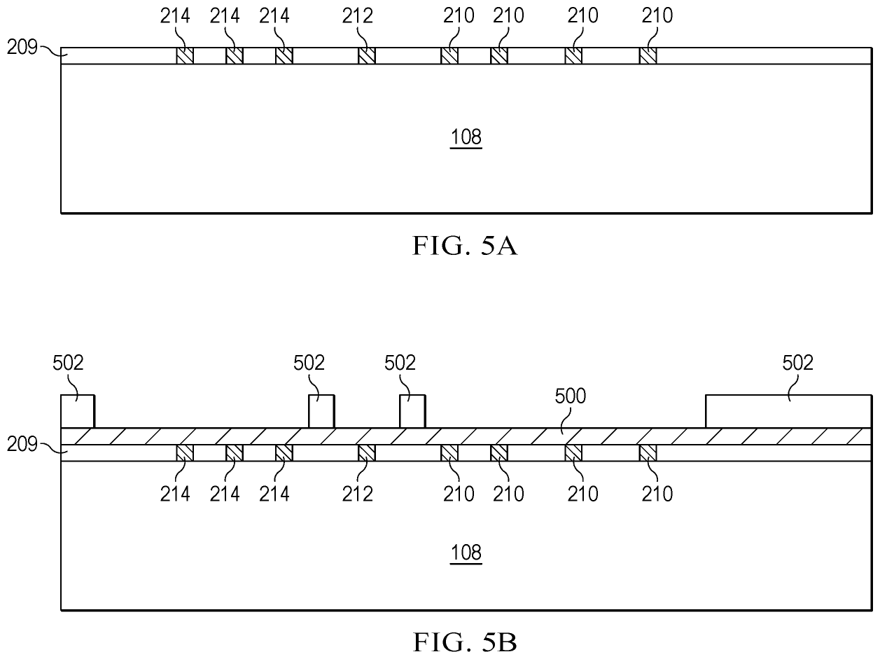

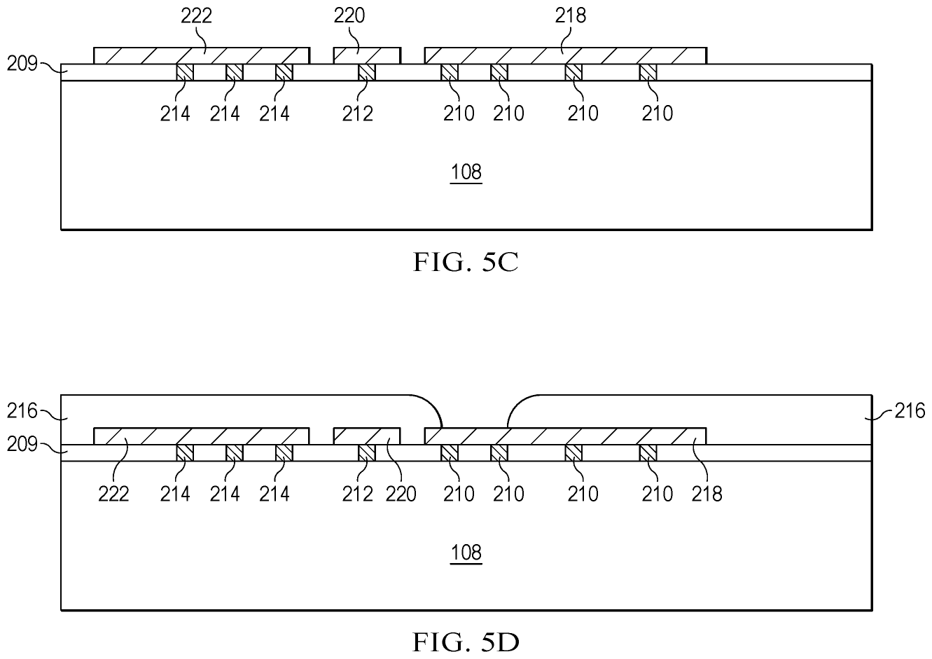

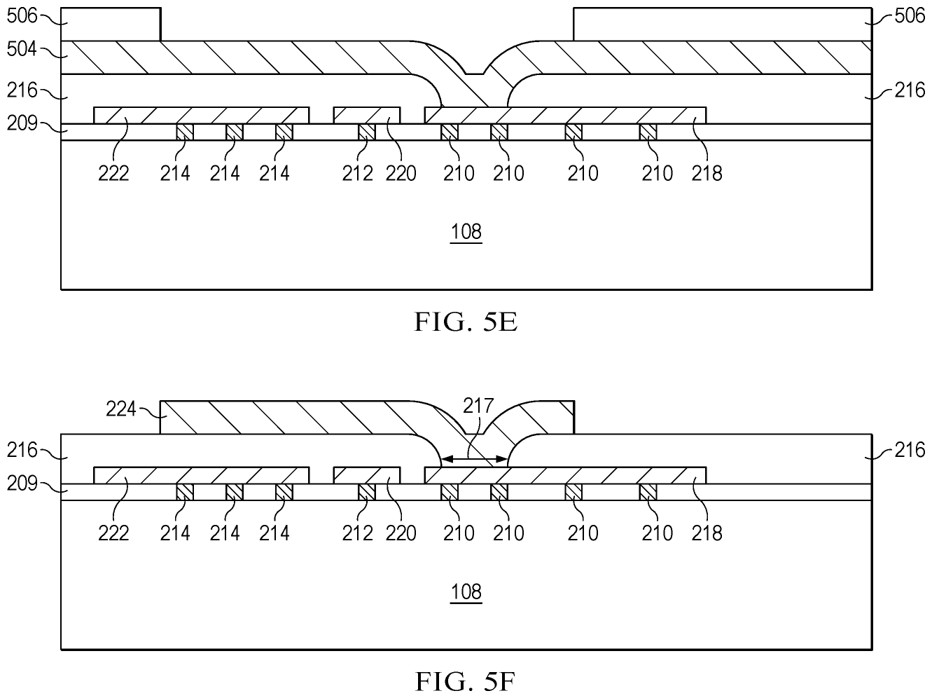

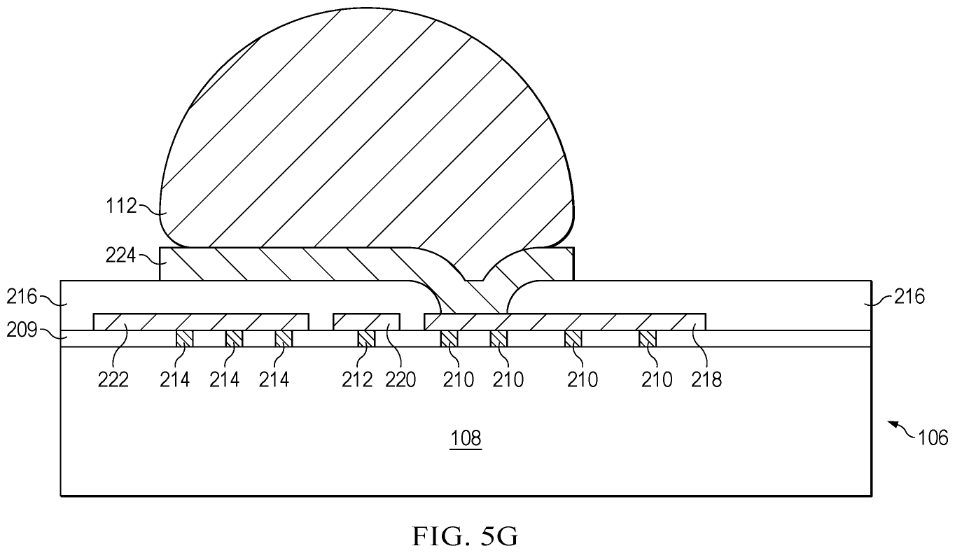

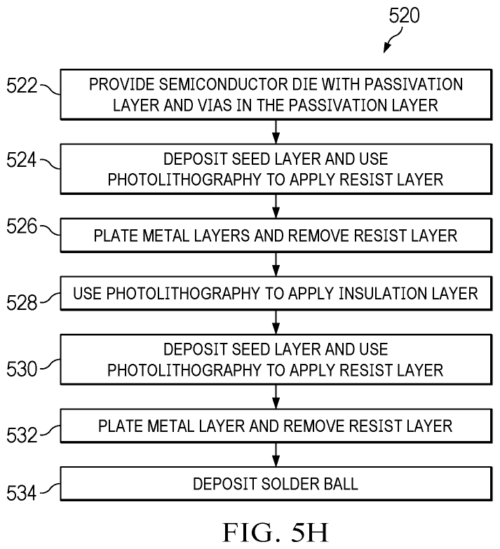

FIGS. 5A-5G is a process flow of a technique for manufacturing a CSP implementing an efficient RDL topology, in accordance with various examples. FIG. 5H is a flow diagram of a method 520 for manufacturing a CSP implementing an efficient RDL topology, in accordance with various examples. Accordingly, the process flow of FIGS. 5A-5G is now described in parallel with the method 520. The process flow and the method 520 may be used to form the CSP 106 of FIG. 2, for example.

The method 520 begins with providing a semiconductor die having a passivation layer and vias in the passivation layer (522). FIG. 5A shows the semiconductor die 108 with a passivation layer 209 positioned on the semiconductor die 108. The passivation layer 209 includes vias 210, 212, 214. The vias 210, 212, 214 may be formed, for instance, using a photolithography process in the passivation layer 209 to form orifices that are filled with a suitable seed layer and plated to form the vias 210, 212, 214 (e.g., using copper).

The method 520 includes depositing a seed layer and using photolithography processes to apply a photoresist layer (also called a resist layer) (524). FIG. 5B shows the deposition of a seed layer 500 and the application of a resist layer 502. Photolithography processes form the patterns in the resist layer 502.

The method 520 includes plating metal layers and removing the resist layer (526). FIG. 5C shows the plated metal layers 218, 220, 222, and the resist layer 502 (FIG. 5B) has been removed. The metal layer 218 abuts the vias 210, the metal layer 220 abuts the via 212, and the metal layer 222 abuts the vias 214.

The method 520 includes using photolithography to apply an insulation layer (528). FIG. 5D shows an insulation layer 216 that has been patterned using photolithography processes. As shown, the insulation layer 216 abuts the metal layers 218, 220, 222 as well as the passivation layer 209.

The method 520 includes depositing a seed layer and using photolithography to apply a resist layer (530). FIG. 5E shows the deposition of a seed layer 504 and the application of a resist layer 506. Photolithography processes form the patterns in the resist layer 506.

The method 520 includes plating a metal layer and removing the resist layer (532). FIG. 5F shows a metal layer 224 formed using a plating technique, as well as the resist layer 506 (FIG. 5E) having been removed. The metal layer 224 abuts the metal layer 218 through the orifice 217, as shown.

The method 520 includes depositing a solder ball (534). FIG. 5G shows the solder ball 112 having been deposited on the metal layer 224. The solder ball 112 may be used to couple the example CSP 106 of FIG. 5G to any suitable electronic device, such as a PCB.

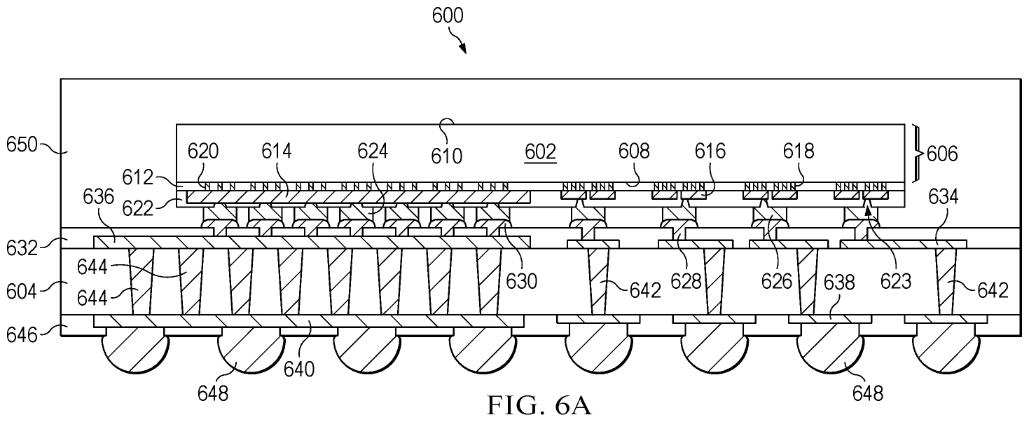

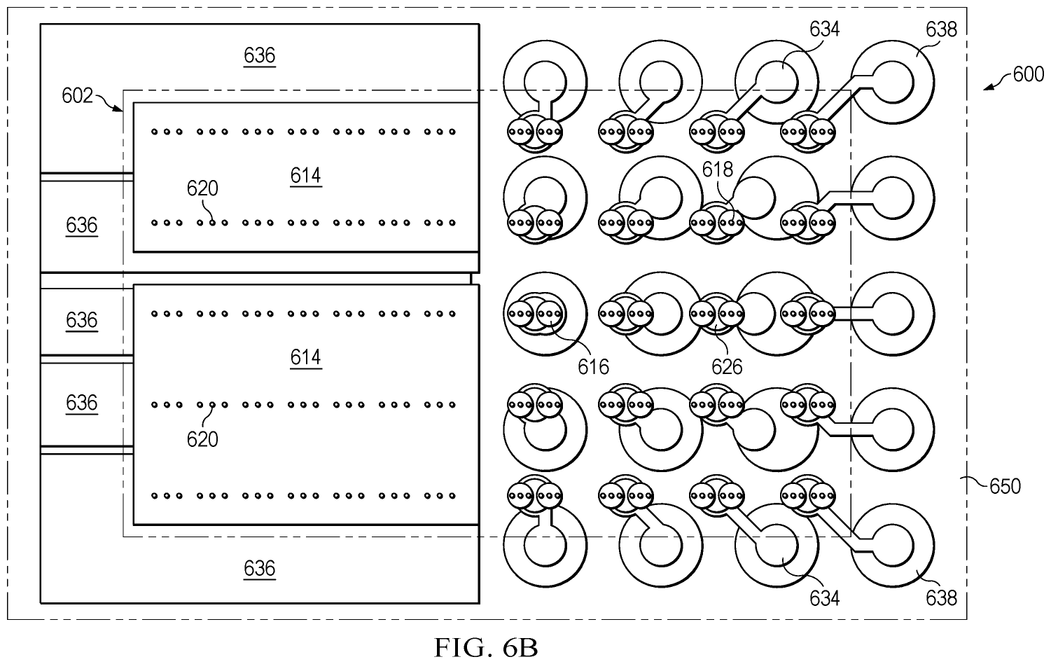

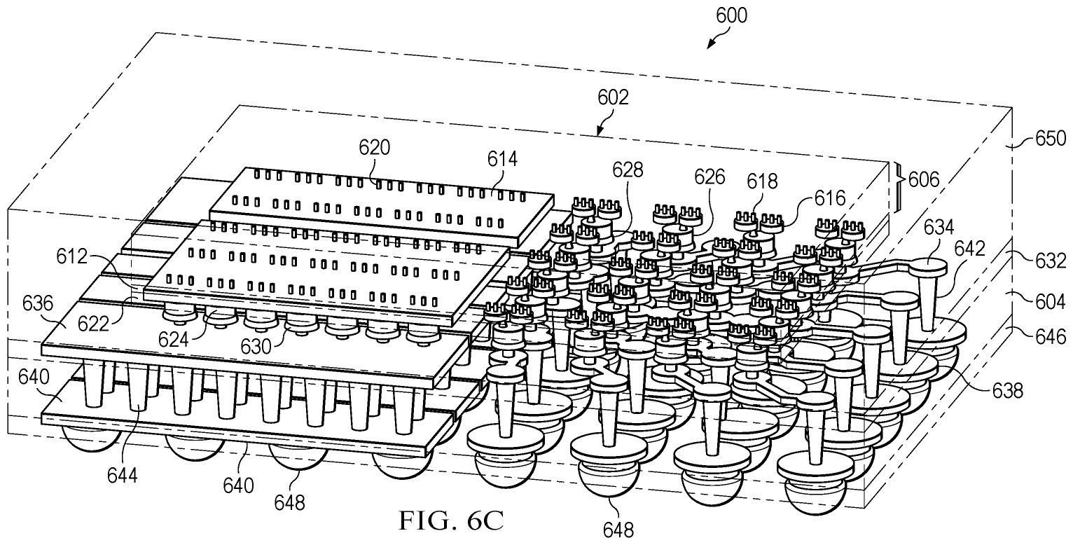

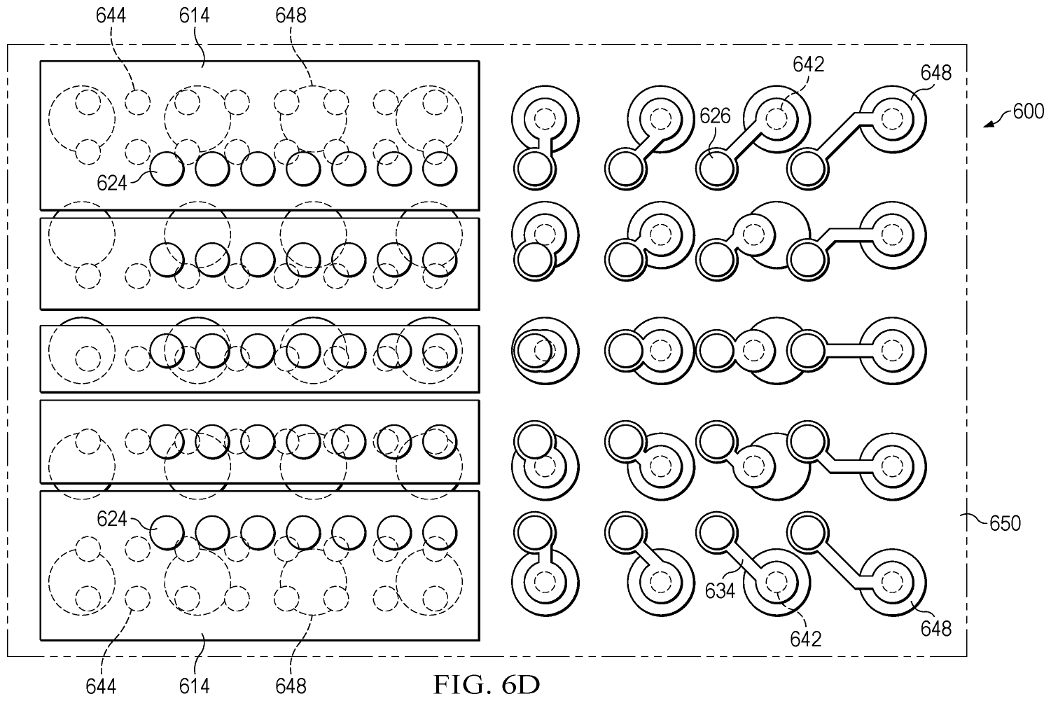

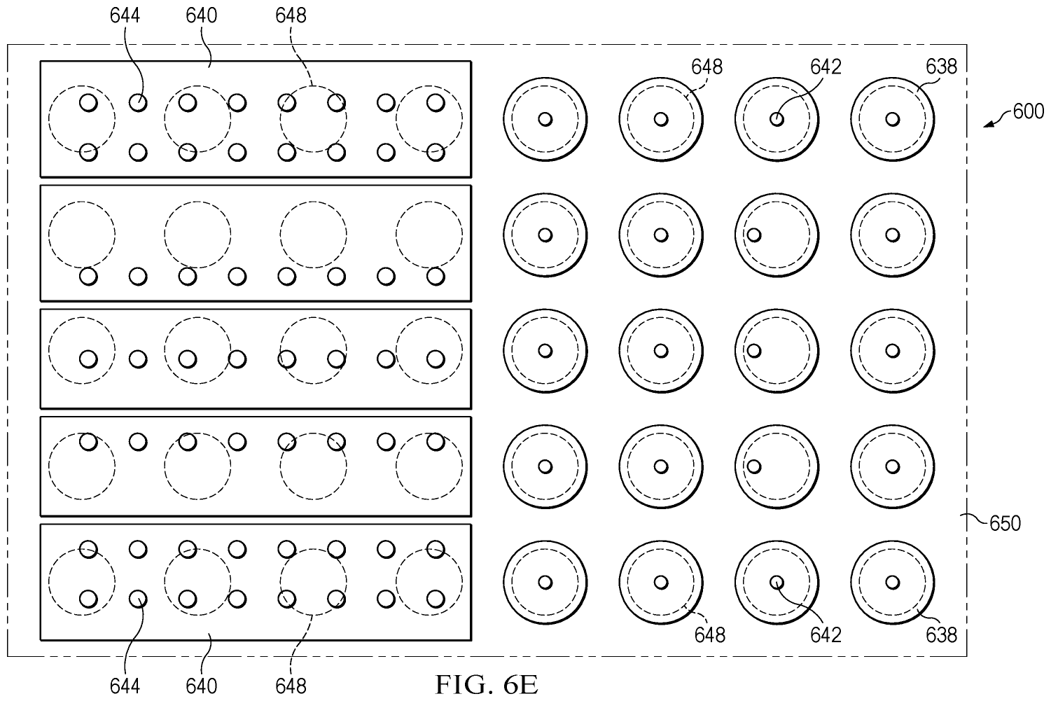

FIG. 6A is a cross-sectional view of a semiconductor package 600 including a semiconductor die 602 and a ball grid array (BGA) substrate 604 having signal and power conductors, in accordance with various examples. More specifically, the semiconductor die 602 includes a semiconductor portion 606 (e.g., silicon, gallium nitride); a device side 608 on, in, and/or near which circuitry is formed; and a non-device side 610 that does not include circuitry. The device side 608 of the semiconductor die 602 faces downward, toward the bottom of the semiconductor package 600, and the non-device side 610 of the semiconductor die 602 faces upward, toward the top of the semiconductor package 600. The device side 608 may include one or more metal layers (which are not expressly depicted) to facilitate the exchange of data signals and/or power. Collectively, these metal layers are referred to herein as “back end of line” (BEOL) metallization. The metal layers in the BEOL metallization may include aluminum or copper. The metal layers in the BEOL metallization have vertical thicknesses ranging from 0.2 microns to 3 microns, with a thickness below this range being disadvantageous because of unacceptably low current carrying ability, and with a thickness above this range being disadvantageous because of significantly diminished improvements in current carrying ability.

A planarized passivation layer 612 is on the device side 608 of the semiconductor package 600. The passivation layer 612 protects circuitry in, on, and/or near the device side 608 of the semiconductor package 600 from damage (e.g., oxidation). The semiconductor package 600 includes a metal layer including metal members 614, 616 (e.g., copper). The metal members 614, 616 are oriented horizontally and thus may be referred to herein as horizontal metal members. Similarly, other metal members described herein that are oriented horizontally like the metal members 614, 616 may also be referred to herein as horizontal metal members. Non-metal members that are oriented horizontally may be referred to herein as horizontal members, horizontal components, etc. To be oriented horizontally, a structure must have its maximal dimension extending along the horizontal direction. As may be the case with any other components described herein (e.g., metal members 636, 640 described below), the scope of this disclosure is not limited to any particular number of metal members 614, 616. Similarly, as may be the case with any other components described herein (e.g., metal members 634, 638 described below), although this description refers to metal member 616 in the singular sense for clarity of explanation, as FIG. 6A shows, multiple metal members 616 may be included. The metal member 616 may be configured to carry data signals and may be coupled to a data signal terminal, and the metal member 614 may be configured to carry power and may be coupled to a power terminal. The vertical thickness of the metal member 616 ranges from 4 microns to 25 microns, with a thickness below this range being disadvantageous because of unacceptably poor current carrying ability, and with a thickness above this range being disadvantageous because of significantly diminished improvements in current carrying ability. The metal member 614, which carries power, has a vertical thickness ranging from 10 microns to 25 microns, with a thickness below this range being disadvantageous because of unacceptably poor current carrying ability, and with a thickness above this range being disadvantageous because of significantly diminished improvements in current carrying ability.

The metal member 616 is coupled to the BEOL metallization (e.g., the BEOL metallization metal layer closest to the metal member 616) by way of vias 618 extending through the passivation layer 612. The metal member 614 is coupled to the BEOL metallization by way of vias 620 extending through the passivation layer 612. The vias 618 have a maximum cross-sectional diameter ranging from 1 micron to 10 microns, with a diameter below this range being disadvantageous because unacceptably high costs in patterning the via, and with a diameter above this range being disadvantageous because of unacceptably high inefficiencies in area usage. The vias 620 have a maximum cross-sectional diameter ranging from 0.5 microns to 10 microns, with a diameter below this range being disadvantageous because of unacceptably high costs of patterning vias, and with a diameter above this range being disadvantageous because unacceptably high inefficiencies in area usage. The vias 618, 620 may comprise tungsten, copper, a suitable alloy, or any other suitable conductive material.

A polyimide layer 622 abuts the metal members 614, 616. The polyimide layer 622 has a vertical thickness ranging from 2 to 50 microns, with a thickness below this range being disadvantageous because of unacceptably reduced stress buffering ability, and with a thickness above this range being disadvantageous because of unacceptably increased costs. Another insulating and/or protective material may be useful in lieu of polyimide.

Metal posts 624, 626 are coupled to the metal members 614, 616, respectively. As FIG. 6A shows, the metal posts 626 are in vertical alignment with the metal members 616. As FIG. 6A also shows, the metal posts 624 are in vertical alignment with the metal members 614. To be in vertical alignment, a first structure must overlap with a second structure in the vertical direction. In examples, the metal posts 624, 626 comprise copper, although other metals and alloys may be suitable. The vertical thickness of the metal post 626, which is configured to carry data signals, ranges from 10 microns to 80 microns, with thicknesses below this range being disadvantageous because a standoff is necessary to apply underfill, and with thicknesses above this range being disadvantageous because of an unacceptable increase in form factor. The vertical thickness of the metal post 624, which is configured to carry power, ranges from 10 microns to 80 microns, with thicknesses below this range being disadvantageous because a standoff is necessary to apply underfill, and with thicknesses above this range being disadvantageous because of an unacceptable increase in form factor.

The polyimide layer 622 includes an orifice 623 through which the metal post 626 couples to a first metal member 616, as shown. The orifice 623 has a maximum horizontal dimension (diameter) of less than 50 microns. Because the maximal horizontal dimension is less than 50 microns, the width of the metal filling in the orifice 623 is reduced, and likewise, the horizontal area of the metal member 616 to which the metal post 626 connects through the orifice 623 is reduced. As a result, more space is available for other components of the semiconductor package 600, such as other metal members 616. As shown in this example, multiple metal members 616 are in vertical alignment with the metal post 626, which represents a more efficient and complete use of space relative to other technologies and which is made possible by an orifice 623 that is less than 50 microns in maximal horizontal diameter.

A solder bump 628 is coupled to the metal post 626, and a solder bump 630 is coupled to the metal post 624. The solder bumps 628, 630 comprise an alloy of tin (80-100%), silver (1-5%), copper (0-5%), and nickel (0-1%). The solder bump 628, which is configured to carry data signals, has a vertical thickness ranging from 10 microns to 80 microns, with a thickness less than this range being disadvantageous because a standoff is necessary to apply underfill, and with a thickness above this range being disadvantageous because of an unacceptable increase in form factor. The solder bump 630, which is configured to carry power, has a vertical thickness ranging from 10 microns to 80 microns, with a thickness less than this range being disadvantageous because a standoff is necessary to apply underfill, and with a thickness above this range being disadvantageous because of an unacceptable increase in form factor.

The BGA substrate 604 may be composed of any suitable material, such as FR-4, BT, polyimide, AJINIMOTO® Build-Up Film (ABF), and epoxy. In some examples, the BGA substrate 604 includes a core, and in other examples, the BGA substrate 604 is coreless. The BGA substrate 604 has a vertical thickness ranging up to 500 microns, with a thickness above this range being disadvantageous because of an unacceptable increase in form factor. A solder mask 632 is on the BGA substrate 604. The solder mask 632 has a vertical thickness ranging from 5 to 30 microns, with a thickness below this range being disadvantageous because of a resulting lack of structural integrity, and with a thickness above this range being disadvantageous because of an unacceptable risk in form factor. The solder mask 632 is on metal members 634 and 636, which may be composed of any suitable metal or alloy, such as copper. The metal members 634 and 636 are also on the BGA substrate 604. The metal member 634 is configured to carry data signals, and the metal member 636 is configured to carry power. The metal member 634 has a vertical thickness ranging from 5 to 50 microns, with a thickness below this range being disadvantageous because of an unacceptably low level of current carrying capability and reliability, and with a thickness above this range being disadvantageous because of an unacceptable increase in form factor. The metal member 636 has a vertical thickness ranging from 5 to 50 microns, with a thickness below this range being disadvantageous because of an unacceptably low level of current carrying capability and reliability, and with a thickness above this range being disadvantageous because of an unacceptable increase in form factor.

Metal members 638 and 640 are on an opposite surface of the BGA substrate 604 from the surface of the BGA substrate 604 on which the metal members 634 and 636 are positioned. The metal member 638 is configured to carry data signals and has a vertical thickness ranging from 5 to 50 microns, with a thickness below this range being disadvantageous because of an unacceptably low level of current carrying ability and reliability, and with a thickness above this range being disadvantageous because of an unacceptable increase in form factor. The metal member 640 is configured to carry power and has a vertical thickness ranging from 5 to 50 microns, with a thickness below this range being disadvantageous because of reduced current carrying ability and reliability, and with a thickness above this range being disadvantageous because of an unacceptable increase in form factor.

One or more vias 642 couple the metal member 634 to the metal member 638 by extending through the BGA substrate 604. The one or more vias 642 are composed of any suitable metal or alloy, such as copper. Each of the one or more vias 642, which is configured to carry data signals, has a maximum cross-sectional diameter ranging from 20 microns to 120 microns, with a diameter below this range being disadvantageous because of an unacceptable increase in costs, and with a diameter above this range being disadvantageous because of an unacceptable increase in form factor.

One or more vias 644 couple the metal member 636 to the metal member 640 by extending through the BGA substrate 604. The one or more vias 644 are composed of any suitable metal or alloy, such as copper. Each of the one or more vias 644, which is configured to carry power, has a maximum cross-sectional diameter ranging from 20 microns to 120 microns, with a diameter below this range being disadvantageous because of an unacceptable increase in costs, and with a diameter above this range being disadvantageous because of an unacceptable increase in form factor.

A solder mask 646 abuts the metal members 638, 640 and the surface of the BGA substrate 604 on which the metal members 638, 640 are positioned. The solder mask 646 has a vertical thickness ranging from 5 to 30 microns, with a thickness below this range being disadvantageous because of an unacceptable increase in costs, and with a thickness above this range being disadvantageous because of an unacceptable increase in form factor.

Solder balls 648 are coupled to the metal members 638 and 640. The solder balls 648 comprise tin (60%-99.5%), silver (0.1%-5%), and copper (0.1%-3%), and thus may be referred to as SAC (“S” representing “Sn,” or tin; “A” representing “Ag,” or silver; and “C” representing “Cu,” or copper) solder balls. Such SAC solder balls 648 may mitigate voiding at the interface between solder and metal members 638, 640 caused by electromigration. The solder balls 648 have a maximum cross-sectional diameter ranging from 100 to 600 microns, with a diameter below this range being disadvantageous because of an unacceptable reduction in current carrying ability, and with a diameter above this range being disadvantageous because of an unacceptable increase in form factor. The solder balls 648 may couple to a PCB (not expressly shown).

In examples, the various structures of the semiconductor package 600 are covered by a mold compound 650, as shown. In some examples, the mold compound 650 is omitted.

FIG. 6B is a top-down view of the structure of FIG. 6A, in accordance with various examples. FIG. 6C is a perspective view of the structure of FIG. 6A, in accordance with various examples.

FIG. 6D is a top-down, multi-layer view of the semiconductor package 600, in accordance with various examples. FIG. 6E is a top-down, multi-layer view of the semiconductor package 600, in accordance with various examples. More particularly, FIGS. 6D and 6E show the BGA substrate 604 of FIGS. 6A-6C. To reduce complexity and manage space constraints, the semiconductor package 600 as shown in FIGS. 6D and 6E does not have the identical configuration of the semiconductor package 600 as shown in FIGS. 6A-6C, but the configurations are similar and exhibit the same novel features of FIGS. 6A-6C.

As FIGS. 6A-6D show, the top surface of the semiconductor die 602 may be exposed to an exterior of the mold compound 650. However, in some examples, the mold compound 650 may fully cover the semiconductor die 602, including the top surface of the semiconductor die 602. Exposing the top surface of the semiconductor die 602 achieves superior heat dissipation. In an experiment, a semiconductor die 602 exposed to an exterior of the semiconductor package 600 achieved a 2 degree Celsius reduction in maximum semiconductor die 602 temperature, a 3.5 degree Celsius per watt reduction in junction-to-ambient thermal resistance (theta-JA), and a 3 degree Celsius per watt reduction in junction-to-board thermal resistance (psi-JB), relative to a semiconductor package of the same structure but having a non-exposed top surface of the semiconductor die. Semiconductor packages 600 including metal layers having vertical thicknesses in the upper quartile of the thickness ranges provided above achieved a 0.6 degree Celsius reduction in maximum semiconductor die temperature, a 1 degree Celsius per watt reduction in theta-JA, and a 1.1 degree Celsius per watt reduction in psi-JB, relative to a semiconductor package of the same structure but having thinner metal layers. Semiconductor packages 600 including two times or three times the number of vias included in other semiconductor packages provided a 1 degree Celsius reduction in maximum semiconductor die temperature, a 0.9 degree Celsius per watt reduction in theta-JA, and a 1.5 degree Celsius per watt reduction in psi-JB. Semiconductor packages 600 including an exposed top surface of the semiconductor die 602, two times to three times the number of vias included in other semiconductor packages, and top-quartile metal member thicknesses as described above resulted in a 3.5 degree Celsius reduction in maximum semiconductor die temperature, a 6.3 degree Celsius per watt reduction in theta-JA, and a 5.6 degree Celsius per watt reduction in psi-JB, relative to semiconductor packages lacking these features.

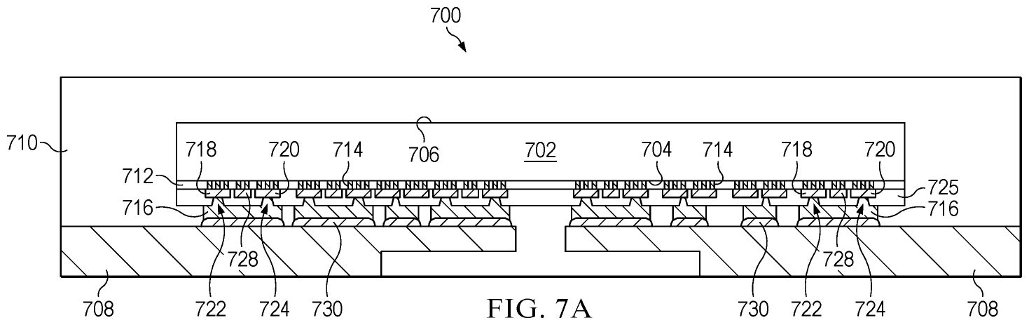

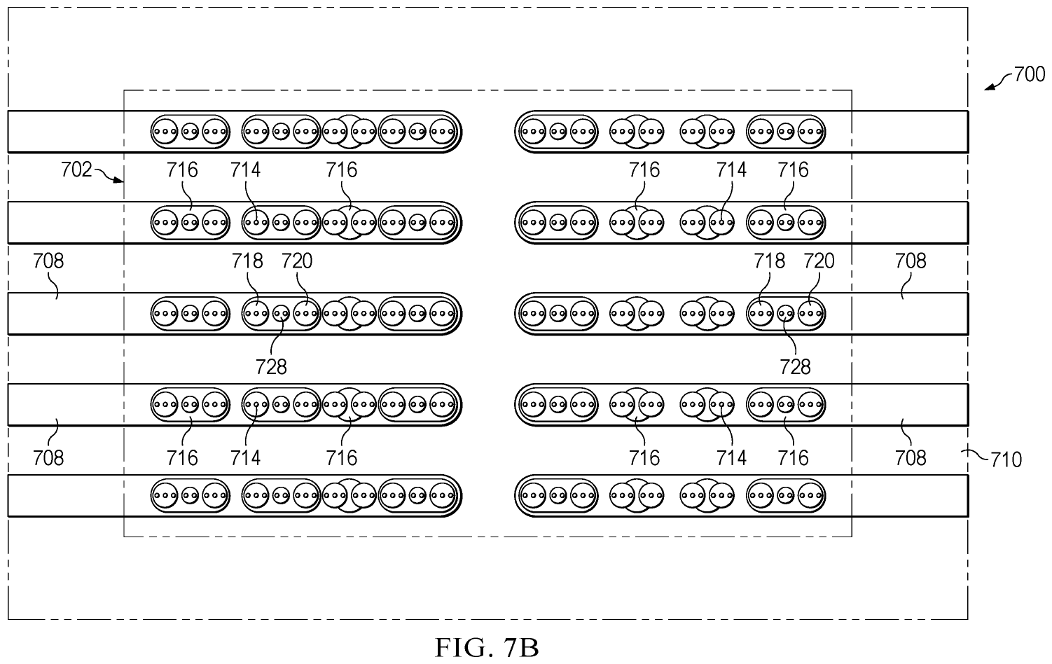

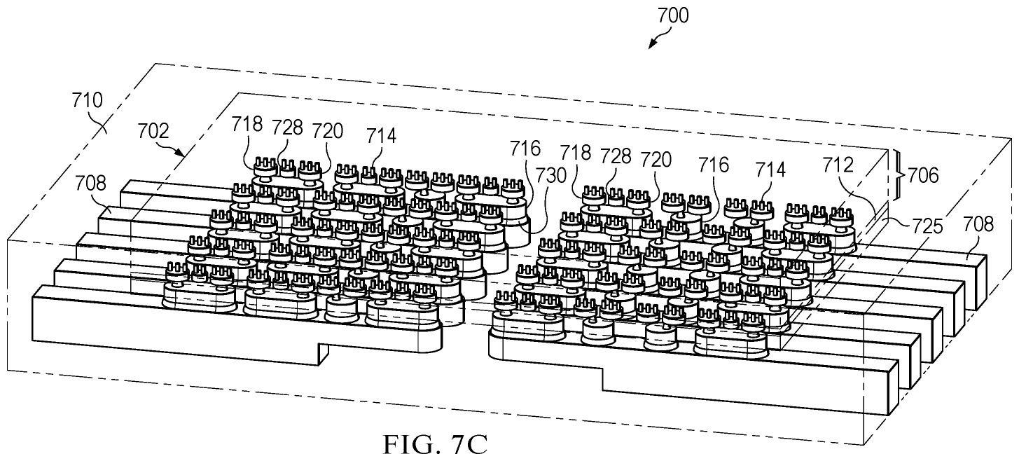

FIG. 7A is a profile, cross-sectional view of a semiconductor package 700 (e.g., a quad flat no lead (QFN) package) implementing an efficient RDL topology, in accordance with various examples. The semiconductor package 700 includes a semiconductor die 702 having a device side 704 that includes circuitry formed therein. The semiconductor die 702 also includes a non-device side 706 opposite the device side 704. The semiconductor die 702 includes conductive terminals 708 and a mold compound 710 covering the semiconductor die 702 and conductive terminals 708. The conductive terminals 708 are exposed to an exterior (e.g., bottom) surface of the semiconductor package 700, such that the conductive terminals 708 may be coupled to another component external to the semiconductor package 700. For example, the conductive terminals 708 could be soldered to a printed circuit board.

The semiconductor package 700 includes a planarized passivation layer 712 and multiple vias 714 extending through the planarized passivation layer 712. A polyimide layer 725 may abut the planarized passivation layer 712. The semiconductor package 700 also includes metal posts 716, metal members 718 and 720, components 728, and solder bump 730. The mold compound 710 includes orifices 722, 724 through which the metal posts 716 couple to metal members 718, 720. In some examples, the orifices 722, 724 are in the polyimide layer 725. The orifices 722, 724 have maximal horizontal dimensions (diameters) less than 50 microns. Having maximal horizontal dimensions less than 50 microns enables the metal filling the orifices 722, 724 to have a smaller horizontal area, and, by extension, the metal members 718, 720 also may have smaller horizontal areas. Because the metal members 718, 720 have smaller horizontal areas, space is created for additional components and thus a more efficient use of space. For example, components 728 may be included in a space that otherwise may have been occupied by the metal member(s) 718, 720. As shown, because additional space is created for components 728, the metal post 716 is in vertical alignment with the metal members 718, 720 and the component 728. In examples, the metal members 718, 720 may represent a common electrical node, while component 728 is a different electrical node. FIG. 7B is a top-down view of the semiconductor package 700 implementing an efficient RDL topology, in accordance with various examples. FIG. 7C is a perspective view of the semiconductor package 700 implementing an efficient RDL topology, in accordance with various examples.

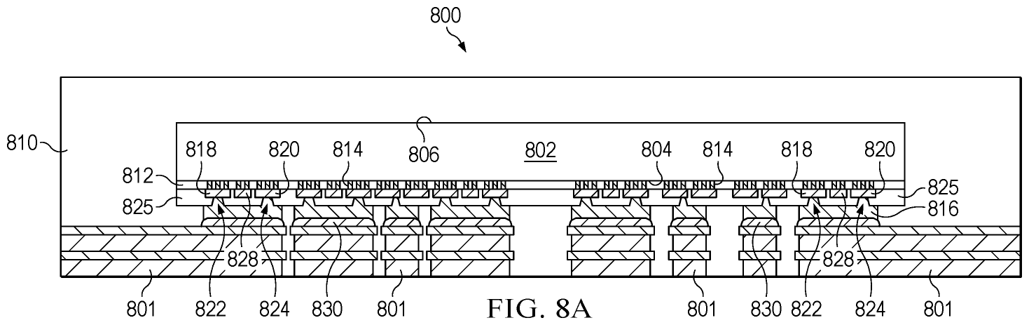

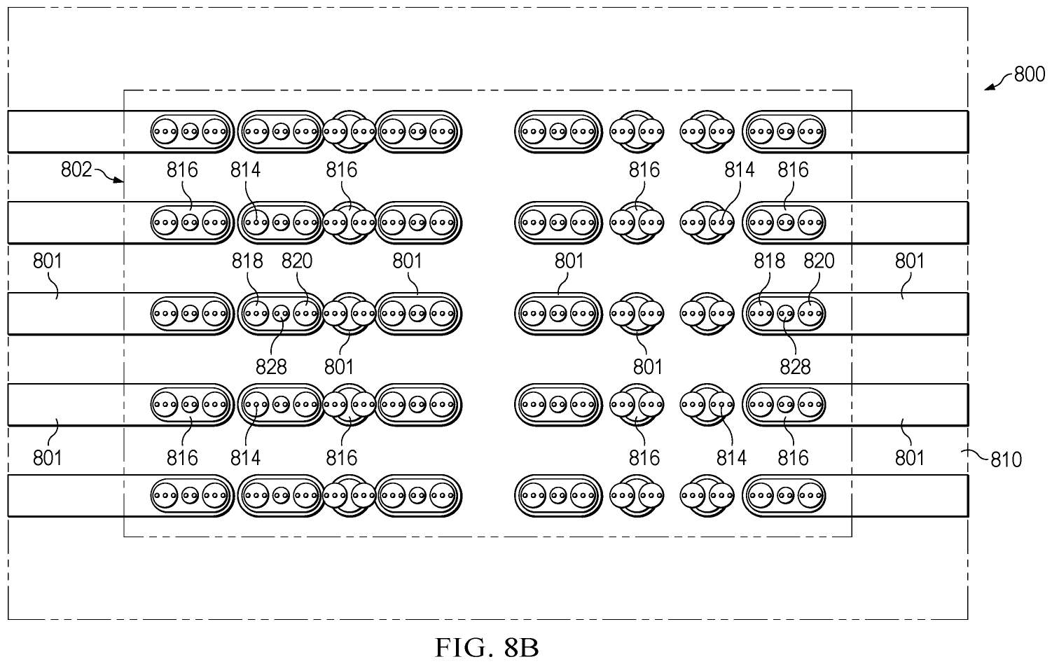

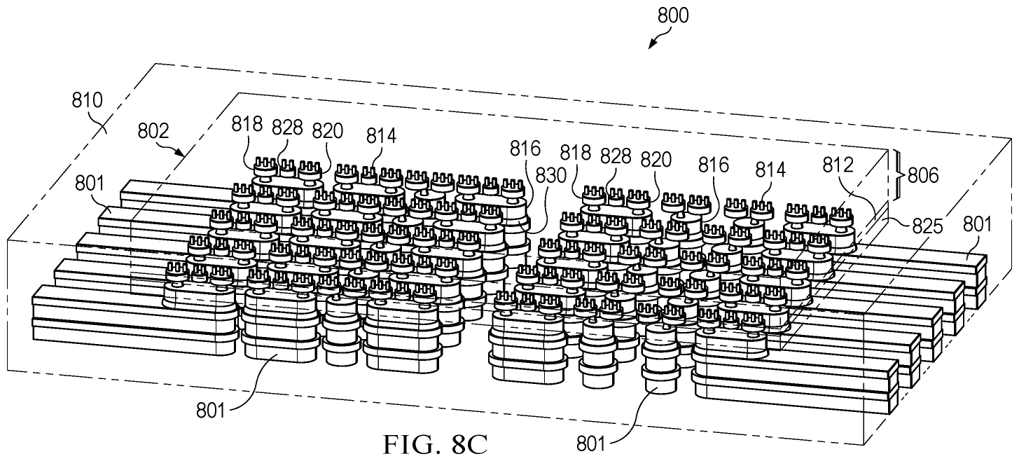

FIG. 8A is a profile, cross-sectional view of a semiconductor package 800 (e.g., a QFN package) implementing an efficient RDL topology, in accordance with various examples. The semiconductor package 800 includes the same components as the semiconductor package 700 described above, with like numerals referring to like components. The semiconductor package 800 includes multiple conductive terminals 801 that are exposed to an exterior surface of the semiconductor package 800, such that the conductive terminals 801 are suitable for coupling (e.g., soldering) to other components (e.g., printed circuit boards).

The mold compound 810 includes orifices 822, 824 through which the metal posts 816 couple to metal members 818, 820. The orifices 822, 824 have maximal horizontal dimensions (diameters) less than 50 microns. Having maximal horizontal dimensions less than 50 microns enables the metal filling the orifices 822, 824 to have a smaller horizontal area, and, by extension, the metal members 818, 820 also may have smaller horizontal areas. Because the metal members 818, 820 have smaller horizontal areas, space is created for additional components and thus a more efficient use of space. For example, components 828 may be included in a space that otherwise may have been occupied by the metal member(s) 818, 820. As shown, because additional space is created for components 828, the metal post 816 is in vertical alignment with the metal members 818, 820 and the component 828. FIG. 8B is a top-down view of the semiconductor package 800 implementing an efficient RDL topology, in accordance with various examples. FIG. 8C is a perspective view of the semiconductor package 800 implementing an efficient RDL topology, in accordance with various examples.

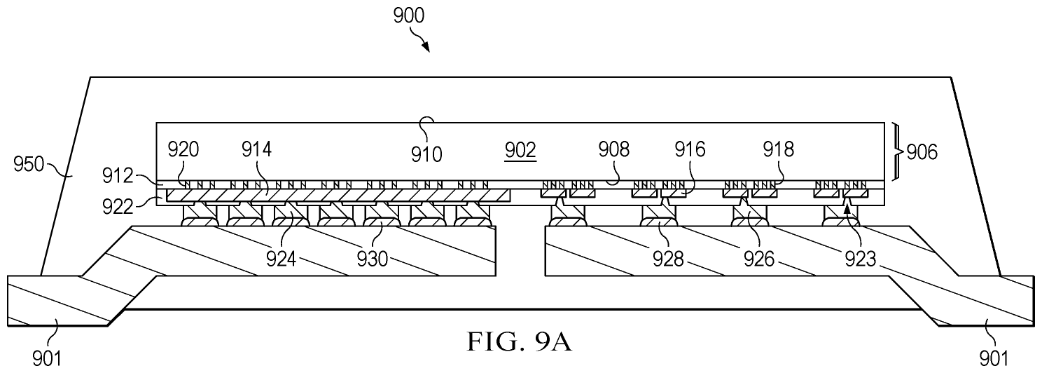

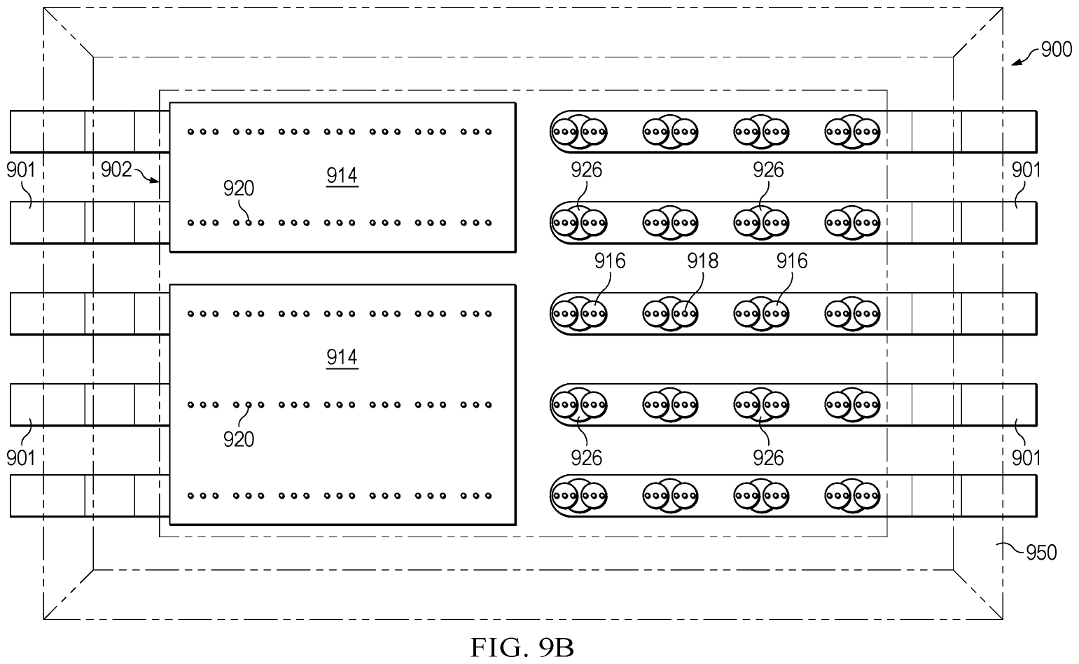

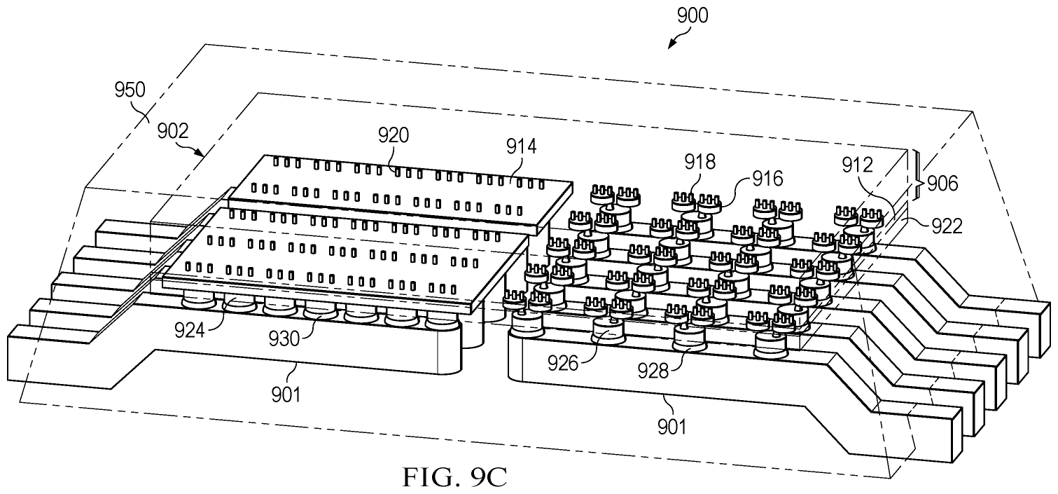

FIG. 9A is a profile, cross-sectional view of a semiconductor package 900 (e.g., a dual in-line package (DIP)) implementing an efficient RDL topology, in accordance with various examples. The semiconductor package 900 includes structures that are similar to those of FIG. 6A, with like numerals referring to like components. Solder bumps 928, 930 are coupled to conductive terminals 901, which may extend from within the semiconductor package 900 to outside the semiconductor package 900 as shown. In examples, the conductive terminals 901 are gullwing style leads. Any number of conductive terminals 901 having any suitable shape and size may be useful and included in the semiconductor package 900. FIG. 9B is a top-down view of the semiconductor package 900 implementing an efficient RDL topology, in accordance with various examples. FIG. 9C is a perspective view of the semiconductor package 900 implementing an efficient RDL topology, in accordance with various examples.

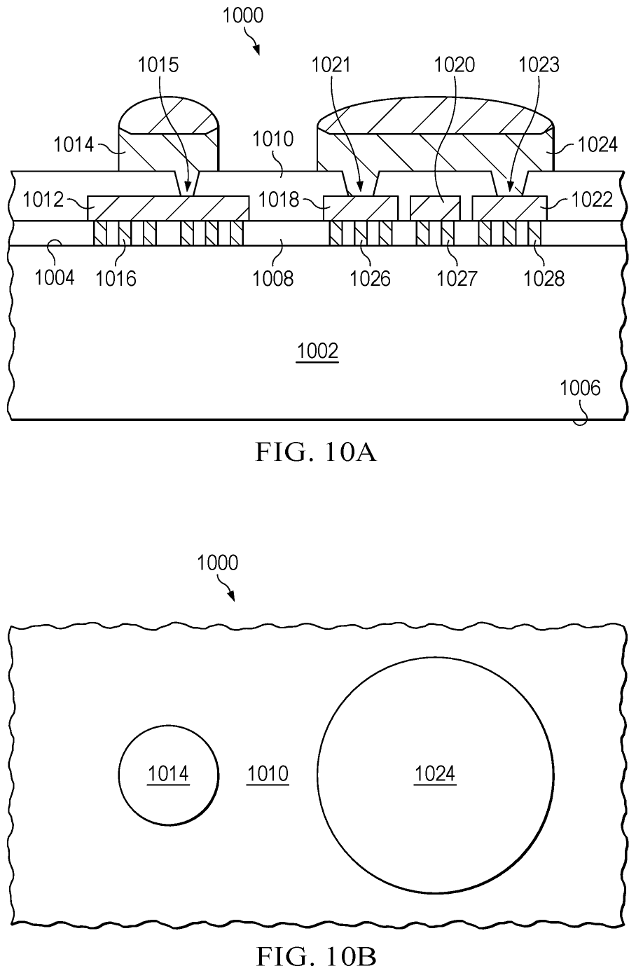

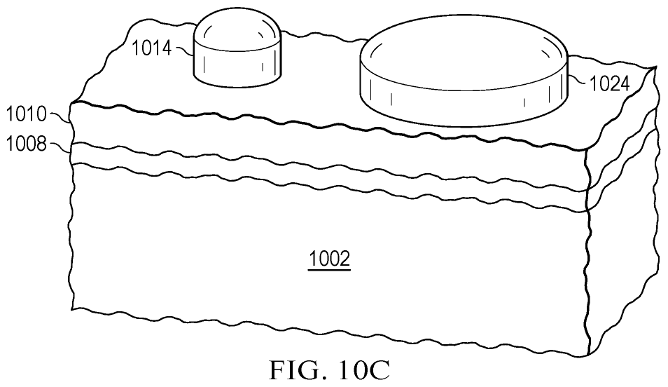

FIG. 10A is a profile, cross-sectional view of a semiconductor package 1000 (e.g., a power wafer chip scale package) implementing an efficient RDL topology, in accordance with various examples. The semiconductor package 1000 includes a semiconductor die 1002 having a device side 1004 including circuitry therein, and a non-device side 1006 opposite the device side 1004. A planarized passivation layer 1008 abuts the device side 1004. A polyimide layer 1010 abuts the planarized passivation layer 1008. A metal member 1012 couples to a metal post 1014 through an orifice 1015 in the polyimide layer 1010. The metal post 1014 has a horizontal diameter ranging from 40 microns to 1000 microns, with a larger diameter being disadvantageous because it would occupy excessive space for non-power applications, and with a smaller diameter being disadvantageous because it would not carry adequate current for data applications. Vias 1016 extend through the planarized passivation layer 1008 to couple circuitry on the device side 1004 to the metal member 1012.

The semiconductor package 1000 also includes metal members 1018, 1020, and 1022. The vertical thickness of each of the metal members 1018, 1020, and 1022 ranges from 4 microns to 25 microns, with a thickness below this range being disadvantageous because of unacceptably poor current carrying ability, and with a thickness above this range being disadvantageous because of significantly diminished improvements in current carrying ability. The metal members 1018 and 1022 couple to a metal post 1024 through orifices 1021, 1023 in the polyimide layer 1010, respectively. The metal post 1024 has a horizontal diameter ranging from 40 microns to 2000 microns, with a smaller diameter being disadvantageous because it would not support adequate current flow for power applications, and with a larger diameter being disadvantageous because it would occupy excessive package space. Vias 1026 couple circuitry on the device side 1004 to the metal member 1018. Vias 1027 couple circuitry on the device side 1004 to the metal member 1020. Vias 1028 couple circuitry on the device side 1004 to the metal member 1022. Vias 1026, 1027, and 1028 extend through the planarized passivation layer 1008, as shown. Each of the vias 1026, 1027, and 1028 has a diameter ranging from 0.5 microns to 10 microns, with a diameter below this range being disadvantageous because of unacceptably high costs of patterning vias, and with a diameter above this range being disadvantageous because of unacceptably high inefficiencies in area usage. Each of the orifices 1021 and 1023 has a maximal horizontal dimension (diameter) less than 50 microns. Because the maximal horizontal dimension of each of the orifices 1021 and 1023 is less than 50 microns, the metal filling the orifices 1021 and 1023 also has a smaller horizontal dimension, as do the metal members 1018, 1022. Consequently, space is freed in which other components (e.g., the metal member 1020) may be positioned, thus using space more efficiently and completely. As shown, the metal members 1018, 1020, and 1022 are vertically aligned with the metal post 1024, which would not be possible were it not for the reduced dimensions of the orifices in the polyimide layer 1010. The metal posts 1014, 1024 may be coupled to other components, such as printed circuit boards, for example using solder. In examples, the metal members 1018, 1022 are part of the same electrical node, while metal member 1020 is a different electrical node. FIG. 10B is a top-down view of the semiconductor package 1000 implementing an efficient RDL topology, in accordance with various examples. FIG. 10C is a perspective view of the semiconductor package 1000 implementing an efficient RDL topology, in accordance with various examples.

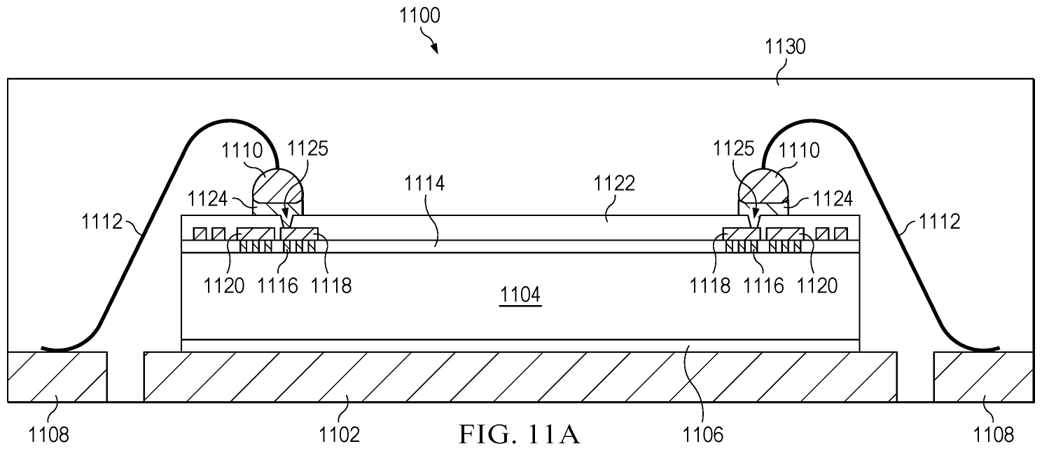

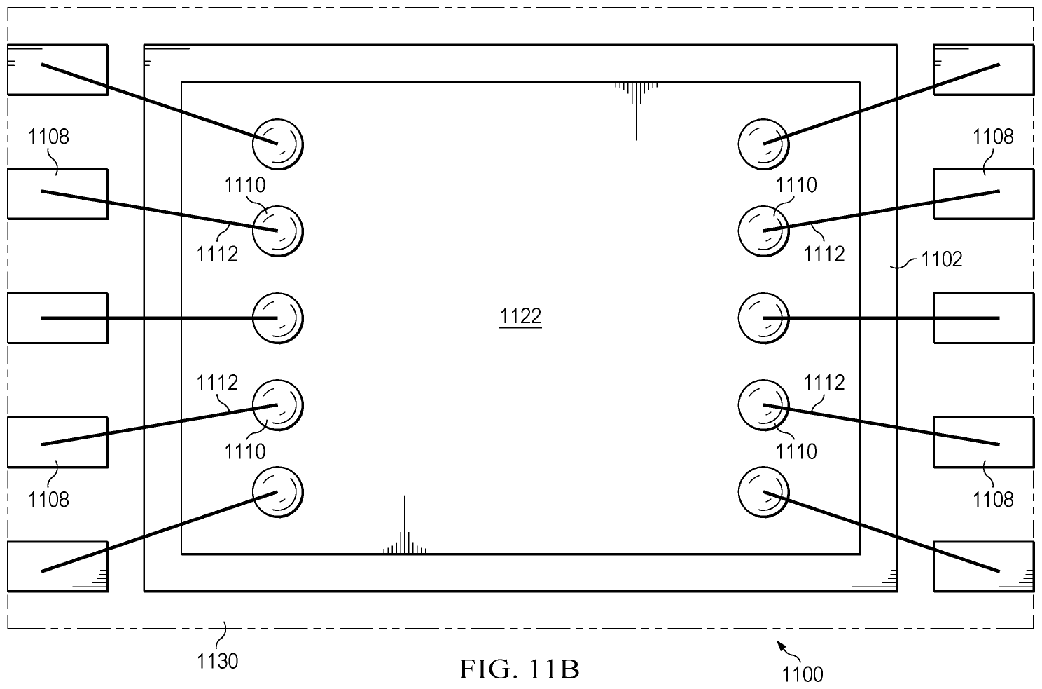

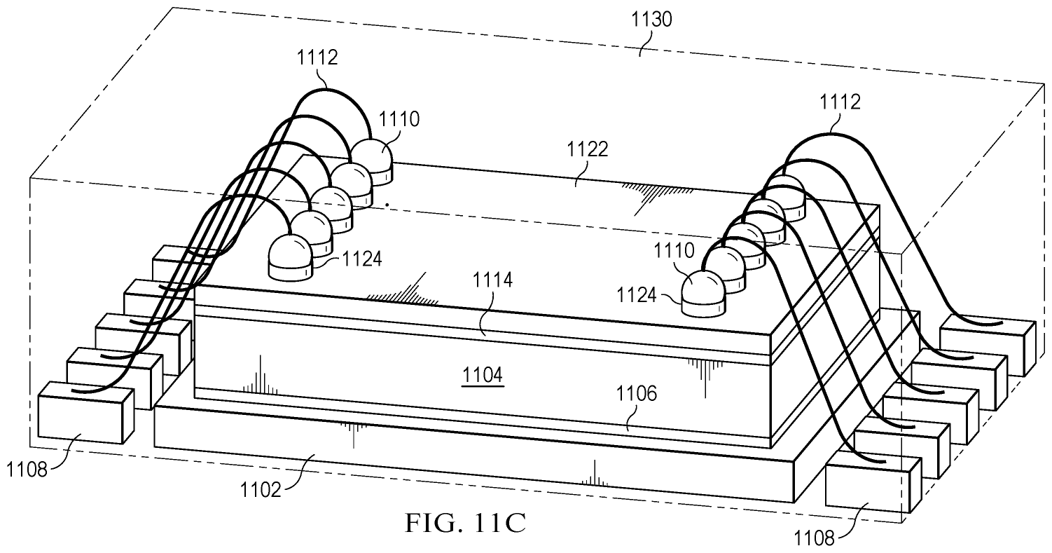

FIG. 11A is a profile, cross-sectional view of a semiconductor package 1100 (e.g., a QFN package) implementing an efficient RDL topology, in accordance with various examples. The semiconductor package 1100 includes a die pad 1102, a semiconductor die 1104 coupled to the die pad 1102 by way of a die attach layer 1106, conductive terminals 1108, wirebond balls 1110 positioned on a device side of the semiconductor die 1104 having circuitry formed therein, and bond wires 1112 coupled to the wirebond balls 1110 and to the conductive terminals 1108. For example, the bond wires 1112 may be stitch bonded to the conductive terminals 1108.

The semiconductor package 1100 also comprises a planarized passivation layer 1114 abutting the device side of the semiconductor die 1104. Vias 1116 couple to circuitry on the device side of the semiconductor die 1104 and extend through the planarized passivation layer 1114. Metal member 1118 couples to the vias 1116. The semiconductor package 1100 also includes metal member 1120. The vertical thickness of each of the metal members 1118, 1120 ranges from 4 microns to 25 microns, with a thickness below this range being disadvantageous because of unacceptably poor current carrying ability, and with a thickness above this range being disadvantageous because of significantly diminished improvements in current carrying ability. A polyimide layer 1122 covers the metal members 1118 and 1120, as shown. A metal post 1124 couples to the metal member 1118 through an orifice 1125. The orifice 1125 has a maximal horizontal dimension (diameter) less than 50 microns. Thus, the metal filling the orifice 1125 also has a maximal horizontal dimension less than 50 microns. As a result of the reduced horizontal dimension of the metal filling and the orifice 1125, the metal member 1118 also has a reduced horizontal dimension, thus creating more space for other components, such as the metal member 1120. In other solutions, the metal member 1118 would have a horizontal dimension so large that there would be no space for other components to be in vertical alignment with the metal post 1124. However, because the metal member 1118 has a reduced horizontal dimension due to the reduced side of the orifice 1125 (relative to other solutions), both metal members 1118 and 1120 are vertically aligned with the metal post 1124. The metal post 1124 has a horizontal diameter ranging from 40 microns to 500 microns, with a smaller diameter being disadvantageous because it would be inadequate to facilitate wirebonding and with a larger diameter being disadvantageous because it would occupy an unacceptably large amount of space relative to the space required to facilitate wirebonding. The metal post 1124 has a thickness ranging from 1 micron to 50 microns, with a larger thickness being disadvantageous because of unacceptably increased manufacturing cost, and with a smaller thickness being disadvantageous because it would be inadequate to facilitate wirebonding. A mold compound 1130 covers the various structures of the semiconductor package 1100 as shown. FIG. 11B is a top-down view of the semiconductor package 1100 implementing an efficient RDL topology, in accordance with various examples. FIG. 11C is a perspective view of the semiconductor package 1100 implementing an efficient RDL topology, in accordance with various examples.

In FIGS. 7A-11C, the physical dimensions of the various structures are the same as the physical dimensions of their respective analogues in FIGS. 6A-6E. For example, the physical dimensions of the metal member 616 are the same as the physical dimensions of the metal members 718, 720. For example, the physical dimensions of the metal post 626 are the same as the physical dimensions of the metal post 716 and/or the metal post 816. The metal members adapted to carry power have the same thickness ranges; the metal members adapted to carry data have the same thickness ranges; the metal posts adapted to carry power have the same thickness and diameter ranges; the metal posts adapted to carry data have the same thickness and diameter ranges; the planarized passivation layers have the same thickness ranges; and the polyimide layers have the same thickness ranges.

The various packages described herein and depicted in the drawings may be of any suitable type. For example, although the various packages are depicted as being a particular type of package (e.g., QFN, dual-inline), such packages may be modified to be QFN packages, dual-inline packages, wirebond-BGA packages, new fine pitch BGA packages, small-outline no lead (SON) packages, quad flat packages (QFP), small outline transistor (SOT) packages, and any and all other suitable types of packages.

The term “couple” is used throughout the specification. The term may cover connections, communications, or signal paths that enable a functional relationship consistent with the description of this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A. Furthermore, a circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. Unless otherwise stated, “about,” “approximately,” or “substantially” preceding a value means +/−10 percent of the stated value. Modifications are possible in the described examples, and other examples are possible, within the scope of the claims.

What is claimed is:

1. A semiconductor package, comprising:
a semiconductor die having a device side with circuitry formed therein;
a passivation layer abutting the device side;
first and second vias coupling to the device side and extending through the passivation layer, the first and second vias having diameters ranging from 0.5 microns to 10 microns;
first and second metal layers coupled to the first and second vias, respectively, the first and second metal layers abutting the passivation layer and having thicknesses in the range of 4 microns to 25 microns;
an insulation layer abutting the first and second metal layers and separating the first and second metal layers, the insulation layer having an orifice in vertical alignment with the second metal layer;
a third metal layer coupled to the second metal layer through the orifice and having a thickness ranging from 10 microns to 80 microns, the third metal layer vertically aligned with the first and second metal layers;
a conductive member coupled to the third metal layer by way of a solder member, the solder member having a thickness ranging from 10 microns to 80 microns; and
a mold compound covering the semiconductor die, the passivation layer, the first and second vias, the first, second, and third metal layers, the insulation layer, the solder member, and at least part of the conductive member.

2. The semiconductor package of claim 1, wherein the semiconductor package includes a substrate having first and second vias extending through the substrate, the first via having a larger diameter than the second via.

3. The semiconductor package of claim 2, wherein the first via has a diameter ranging between 20 microns and 120 microns, and wherein the second via has a diameter ranging between 20 microns and 120 microns.

4. The semiconductor package of claim 2, wherein the substrate is a ball grid array (BGA) substrate.

5. The semiconductor package of claim 1, wherein the package is a quad flat no lead (QFN) package, and wherein the conductive member is a lead of the QFN package.

6. The semiconductor package of claim 1, further comprising a fourth metal layer co-planar with the first and second metal layers, and fourth metal layer having a segment positioned between the first and second metal layers, the fourth metal layer representing a different electrical node than the first and second metal layers.

7. The semiconductor package of claim 6, wherein the first and second metal layers share an electrical node.

8. The semiconductor package of claim 1, wherein the package is a small outline transistor (SOT) package.

9. The semiconductor package of claim 1, wherein the insulation layer includes a second orifice through which the third metal layer is coupled to the first metal layer.

10. The semiconductor package of claim 1, wherein the orifice has a non-circular horizontal cross-sectional shape and has a maximal horizontal dimension less than 50 microns.

11. A power wafer chip scale package (WCSP), comprising:
a semiconductor die having a device side with circuitry formed therein;
a passivation layer abutting the device side;
first, second, and third vias coupled to the device side and extending through the passivation layer;
first, second, and third metal layers coupled to the first, second, and third vias, respectively, the first, and second, and third metal layers abutting the passivation layer, the second metal layer between the first and third metal layers;
an insulation layer abutting the first, second, and third metal layers and separating the first, second, and third metal layers from each other, the insulation layer having orifices vertically aligned with the first and third metal layers but not with the second metal layer; and
a fourth metal layer coupled to the first and third metal layers through the orifices and not coupled to the second metal layer, the fourth metal layer having a horizontal diameter ranging from 40 microns to 2000 microns, the fourth metal layer vertically aligned with the first, second, and third metal layers.

12. The WCSP of claim 11, further comprising a fifth metal layer that is co-planar with the first, second, and third metal layers, and a sixth metal layer coupled to the fifth metal layer through another orifice in the insulation layer, wherein the sixth metal layer has a horizontal diameter ranging from 40 microns to 1000 microns.

13. The WCSP of claim 12, wherein the first, second, third, and fifth metal layers have thicknesses ranging from 4 microns to 25 microns.

14. The WCSP of claim 13, wherein the first, second, and third vias have diameters ranging from 0.5 microns to 10 microns.

15. A semiconductor package, comprising:
a semiconductor die having a device side with circuitry formed therein;
a passivation layer abutting the device side;
a via coupled to the device side and extending through the passivation layer;
first and second metal layers abutting the passivation layer, the first metal layer coupled to the device side by way of the via;
an insulative layer covering the first and second metal layers and abutting the passivation layer, the insulative layer including an orifice vertically aligned with the first metal layer but not with the second metal layer;
a third metal layer abutting the insulative layer and coupled to the first metal layer through the orifice, the third metal layer having a wire bond coupled thereto, the third metal layer vertically aligned with both the first and second metal layers; and
a conductive member coupled to the wire bond, the conductive member exposed to an exterior of the semiconductor package.

16. The semiconductor package of claim 15, wherein the third metal layer has a horizontal diameter of at least 40 microns.

17. The semiconductor package of claim 15, wherein the third metal layer has a thickness of at least 1 micron.

18. The semiconductor package of claim 15, wherein the orifice has a maximal horizontal diameter less than 50 microns.

19. The semiconductor package of claim 15, wherein the package is a QFN package.

20. The semiconductor package of claim 15, wherein a thickness of the first metal layer ranges from 4 to 25 microns.
